(19) United States
(12) Patent Application Publication
(10) Pub. No.: US 2026/0080831 A1
(43) Pub. Date: Mar. 19, 2026

(54) DISPLAY PANEL

(71) Applicant: Yungu (Gu’an) Technology Co., Ltd., Langfang (CN)

(72) Inventors: Lei MI, Langfang (CN); Yanan DING, Langfang (CN); Cuili GAI, Langfang (CN); Xuejie MA, Langfang (CN)

(73) Assignee: Yungu (Gu’an) Technology Co., Ltd., Langfang (CN)

(21) Appl. No.: 19/401,287

(22) Filed: Nov. 25, 2025

Related U.S. Application Data
(63) Continuation of application No. PCT/CN2023/120246, filed on Sep. 21, 2023.

(30) Foreign Application Priority Data
May 31, 2023 (CN) 202310637088.7

(51) Int. Cl. G09G 3/3233; H10D 86/40

(52) U.S. Cl. CPC G09G 3/3233; H10D 86/441; G09G 2300/0819; G09G 2300/0852; G09G 2300/0861; G09G 2310/08; G09G 2320/0233; G09G 2330/021

(57) ABSTRACT

Disclosed is a display panel. A data writing module transmits to a first terminal of a coupling module in a compensation phase, an initial voltage inputted from a first voltage input terminal, and transmits, to the first terminal of the coupling module in a data writing phase, a data voltage inputted from the first voltage input terminal. A second terminal of the coupling module is connected to a control terminal of a driving module. The driving module outputs a driving current to a light-emitting module in a light emission phase through a second terminal of the driving module based on a first power supply voltage inputted from a second voltage input terminal to a first terminal of the driving module and a voltage at the control terminal of the driving module.

### CROSS-REFERENCE TO RELATED APPLICATIONS

The present application is a continuation of International Application No. PCT/CN2023/120246 filed on Sep. 21, 2023, which claims priority to Chinese Patent Application No. 202310637088.7, filed with the China National Intellectual Property Administration on May 31, 2023, which are incorporated herein by reference in their entireties.

### FIELD

Embodiments of the present application relate to the field of display technologies, and in particular, to a display panel.

### BACKGROUND

With the development of display technologies, transparent display apparatuses are increasingly widely used.

The transparent display apparatus includes an array substrate. The array substrate includes pixel circuits and signal traces. In the transparent display apparatus, a structure of the pixel circuit is relatively complex. Correspondingly, the signal traces connected to the pixel circuits are relatively dense.

Therefore, transmittance of the transparent display apparatus is low. As a result, a transparent display effect is poor, and display quality of the transparent display apparatus cannot be ensured.

### SUMMARY

The present application provides a display panel, to simplify a structure of a pixel circuit in a display panel and improve transmittance, thereby improving a transparent display effect and ensuring display image quality of a transparent display apparatus.

An embodiment of the present application provides a display panel, including pixel circuits. Each pixel circuit includes a data writing module, a driving module, a compensation module, a coupling module, a storage module, and a light-emitting module.

The data writing module is connected to a first voltage input terminal. The data writing module is configured to: transmit, to a first terminal of the coupling module in a compensation phase, an initial voltage inputted from the first voltage input terminal; and transmits, to the first terminal of the coupling module in a data writing phase, a data voltage inputted from the first voltage input terminal.

A second terminal of the coupling module is connected to a control terminal of the driving module. The storage module is configured to store a potential at the control terminal of the driving module. A first terminal of the driving module is connected to a second voltage input terminal.

The compensation module is connected between a second terminal of the driving module and the control terminal of the driving module.

The driving module is configured to output a driving current to the light-emitting module in a light emission phase through the second terminal of the driving module based on a first power supply voltage inputted from the second voltage input terminal to the first terminal of the driving module and a voltage at the control terminal of the driving module.

The data writing phase is between the compensation phase and the light emission phase.

The display panel of this embodiment includes the pixel circuits. The pixel circuit includes the data writing module, the driving module, the compensation module, the coupling module, the storage module, and the light-emitting module. The data writing module transmits, to the first terminal of the coupling module in the compensation phase, the initial voltage inputted from the first voltage input terminal, and transmits, to the first terminal of the coupling module in the data writing phase, the data voltage inputted from the first voltage input terminal; and the second terminal of the coupling module is connected to the control terminal of the driving module. In this way, a voltage corresponding to the data voltage is written to the control terminal of the driving module through the data writing module and the coupling module. The compensation module is connected between the second terminal of the driving module and the control terminal of the driving module. In this way, the compensation module may compensate for a threshold voltage of the driving module in the compensation phase. The driving module outputs the driving current to the light-emitting module in the light emission phase through the second terminal of the driving module based on the first power supply voltage inputted from the second voltage input terminal to the first terminal of the driving module and the voltage at the control terminal of the driving module, to drive the light-emitting module. In the display panel of this embodiment, the pixel circuit includes a small number of circuit modules. Correspondingly, the pixel circuit may include a small number of circuit devices, and a structure of the pixel circuit can be simplified. This helps simplify routing in the display panel, and in turn helps improve transmittance of the display panel, thereby helping improve a transparent display effect and ensuring display image quality of a transparent display apparatus.

### BRIEF DESCRIPTION OF THE DRAWINGS

FIG. 1 is a schematic diagram of a structure of a display panel according to an embodiment of the present application;

FIG. 2 is a schematic diagram of a structure of another display panel according to an embodiment of the present application;

FIG. 3 is a schematic diagram of a structure of another display panel according to an embodiment of the present application;

FIG. 4 is a schematic diagram of a type of driving timing for a display panel according to an embodiment of the present application;

FIG. 5 is a schematic diagram of a structure of another display panel according to an embodiment of the present application;

FIG. 6 is a schematic diagram of a structure of another display panel according to an embodiment of the present application;

FIG. 7 is a schematic diagram of a structure of another display panel according to an embodiment of the present application;

FIG. 8 is a schematic diagram of a structure of another display panel according to an embodiment of the present application;

FIG. 9 is a schematic diagram of another type of driving timing for a display panel according to an embodiment of the present application;

FIG. 10 is a schematic diagram of a structure of another display panel according to an embodiment of the present application;

FIG. 11 is a schematic diagram of a structure of still another display panel according to an embodiment of the present application;

FIG. 12 is a schematic diagram of a structure of yet another display panel according to an embodiment of the present application;

FIG. 13 is a schematic diagram of another type of driving timing for a display panel according to an embodiment of the present application;

FIG. 14 is a schematic diagram of a structure of another display panel according to an embodiment of the present application;

FIG. 15 is a schematic diagram of another type of driving timing for a display panel according to an embodiment of the present application;

FIG. 16 is an enlarged view of a part in FIG. 1;

FIG. 17 is a sectional view of a display panel according to an embodiment of the present application;

FIG. 18 is a sectional view of another display panel according to an embodiment of the present application;

FIG. 19 is a schematic diagram of a specific structure of a routing area in FIG. 18;

FIG. 20 is a schematic diagram of a structure of another display panel according to an embodiment of the present application; and

FIG. 21 is a schematic diagram of a structure of a display apparatus according to an embodiment of the present application.

### DETAILED DESCRIPTION OF THE EMBODIMENTS

As described in the background, transmittance of a transparent display apparatus is low. As a result, a transparent display effect is poor, and display quality of the transparent display apparatus cannot be ensured. The inventor finds through research that a cause for the above problem is as follows: In the transparent display apparatus, a 7TIC pixel circuit is usually used. That is, the pixel circuit includes seven transistors and one capacitor. A large number of circuit devices are included in the pixel circuit, and a structure of the pixel circuit is complex. Correspondingly, a large number of signal lines are connected to the pixel circuit, and routing in the display apparatus is dense. The pixel circuit and the signal lines connected to the pixel circuit are located in an active area. Therefore, a large number of circuit devices exist in the active area, and the dense routing causes low transmittance of the transparent display apparatus. As a result, the transparent display effect is poor, and the display quality of the transparent display apparatus cannot be ensured.

On the basis of the above cause, an embodiment of the present application provides a display panel. FIG. 1 is a schematic diagram of a structure of a display panel according to an embodiment of the present application. Referring to FIG. 1, the display panel includes pixel circuits 100. The pixel circuit 100 includes a data writing module 110, a driving module 120, a compensation module 130, a coupling module 140, a storage module 150, and a light-emitting module 160. The data writing module 110 is connected to a first voltage input terminal V1. The data writing module 110 is configured to: transmit, to a first terminal of the coupling module 140 in a compensation phase, an initial voltage inputted from the first voltage input terminal V1; and transmit, to the first terminal of the coupling module 140 in a data writing phase, a data voltage inputted from the first voltage input terminal V1. A second terminal of the coupling module 140 is connected to a control terminal of the driving module 120. The storage module 150 is configured to store a potential at the control terminal G1 of the driving module 120. A first terminal of the driving module 120 is connected to a second voltage input terminal V2. The compensation module 130 is connected between a second terminal of the driving module 120 and the control terminal of the driving module 120. The driving module 120 is configured to output a driving current to the light-emitting module 160 in a light emission phase through the second terminal of the driving module 120 based on a first power supply voltage inputted from the second voltage input terminal V2 to the first terminal of the driving module 120 and a voltage at the control terminal of the driving module 120. The data writing phase is between the compensation phase and the light emission phase.

Specifically, in a frame, an operation process of the pixel circuit includes at least the compensation phase, the data writing phase, and the light emission phase performed in sequence. The operation process of the pixel circuit 100 in a frame is as follows:

In the compensation phase, the initial voltage inputted from the first voltage input terminal V1 is transmitted to the first terminal of the coupling module 140, and a potential at the first terminal of the coupling module 140 is constantly the initial voltage. In the compensation phase, the driving module 120 and the compensation module 130 are both conducted, and a voltage inputted from the second voltage input terminal to the first terminal of the driving module 120 is transmitted to the control terminal of the driving module 120 through the driving module 120 and the compensation module 130. The driving module 120 includes a driving transistor. When a voltage difference between the voltage at the control terminal of the driving module 120 and a voltage at the first terminal of the driving module 120 is equal to a threshold voltage of the driving transistor, the driving module 120 is in a critical off state, to compensate for the threshold voltage of the driving transistor in the compensation phase.

In the data writing phase, the data voltage inputted from the first voltage input terminal V1 is transmitted to the first terminal of the coupling module 140, and the potential at the first terminal of the coupling module 140 jumps from the initial voltage to the data voltage, where the data voltage may be a voltage that is not equal to the initial voltage. In the data writing phase, the compensation module 130 is cut off. Therefore, there is no path for directly writing a voltage to the control terminal of the driving module 120 and the second terminal of the coupling module 140 in the pixel circuit 100. A potential at the second terminal of the coupling module 140 jumps as the potential at the first terminal of the coupling module 140 jumps, that is, the potential at the control terminal of the driving module 120 jumps as the potential at the second terminal of the coupling module 140 jumps, to write a voltage corresponding to the data voltage to the control terminal of the driving module 120 through the data writing module 110 and the coupling module 140. Specifically, when the data voltage varies, a voltage difference between the data voltage and the initial voltage varies as the potential at the first terminal of the coupling module 140 jumps from the initial voltage to the data voltage, that is, a potential change at the first terminal of the coupling module 140 varies. A potential change at the second terminal of the coupling module 140 corresponds to the potential change at the first terminal of the coupling module 140, that is, the potential change at the second terminal of the coupling module 140 corresponds to the data voltage. In this way, the voltage corresponding to the data voltage can be written to the control terminal of the driving module 120 through the data writing module 110 and the coupling module 140.

In this embodiment, in the compensation phase, the voltage inputted from the second voltage input terminal needs to enable the driving module 120 to be conducted, to ensure that the threshold voltage of the driving transistor included in the driving module 120 can be compensated for in the compensation phase.

In the light emission phase, the second voltage input terminal inputs the first power supply voltage to the first terminal of the driving module 120, the driving module 120 is conducted based on the voltage at the control terminal thereof and the first power supply voltage at the first terminal thereof, and the driving module 120 generates a driving current, to drive the light-emitting module 160 to emit light. In addition, because the storage module 150 is provided, the potential at the control terminal of the driving module 120 can be stored and maintained in the light emission phase, and the driving current generated by the driving module 120 changes slightly in the light emission phase, thereby ensuring display uniformity of the display panel.

The display panel of this embodiment includes the pixel circuits. The pixel circuit includes the data writing module, the driving module, the compensation module, the coupling module, the storage module, and the light-emitting module. The data writing module transmits, to the first terminal of the coupling module in the compensation phase, the initial voltage inputted from the first voltage input terminal, and transmits, to the first terminal of the coupling module in the data writing phase, the data voltage inputted from the first voltage input terminal; and the second terminal of the coupling module is connected to the control terminal of the driving module. In this way, the voltage corresponding to the data voltage is written to the control terminal of the driving module through the data writing module and the coupling module. The compensation module is connected between the second terminal of the driving module and the control terminal of the driving module. In this way, the compensation module may compensate for the threshold voltage of the driving module in the compensation phase. The driving module outputs the driving current to the light-emitting module in the light emission phase through the second terminal of the driving module based on the first power supply voltage inputted from the second voltage input terminal to the first terminal of the driving module and the voltage at the control terminal of the driving module, to drive the light-emitting module. In the display panel of this embodiment, the pixel circuit includes a small number of circuit modules. Correspondingly, the pixel circuit may include a small number of circuit devices, and a structure of the pixel circuit can be simplified. This helps simplify routing in the display panel, and in turn helps improve transmittance of the display panel, thereby helping improve a transparent display effect and ensuring display image quality of a transparent display apparatus.

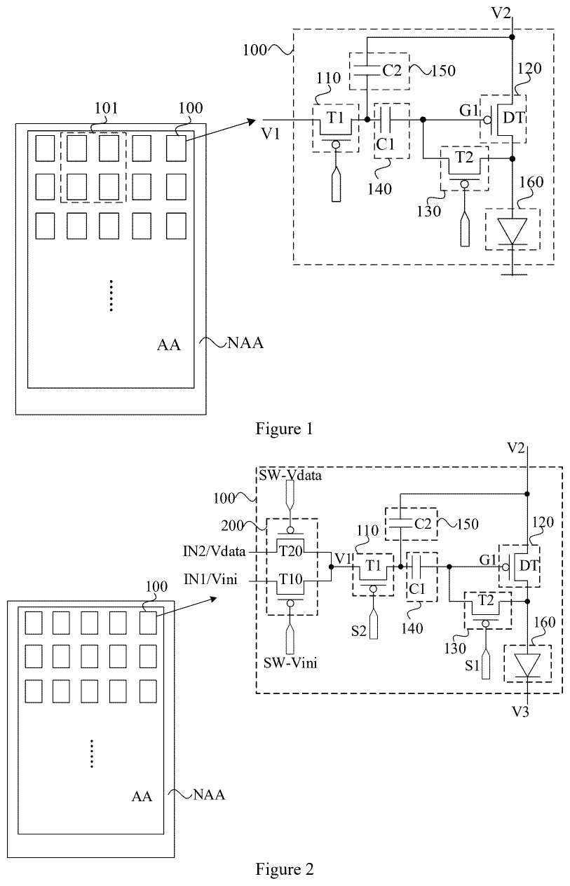

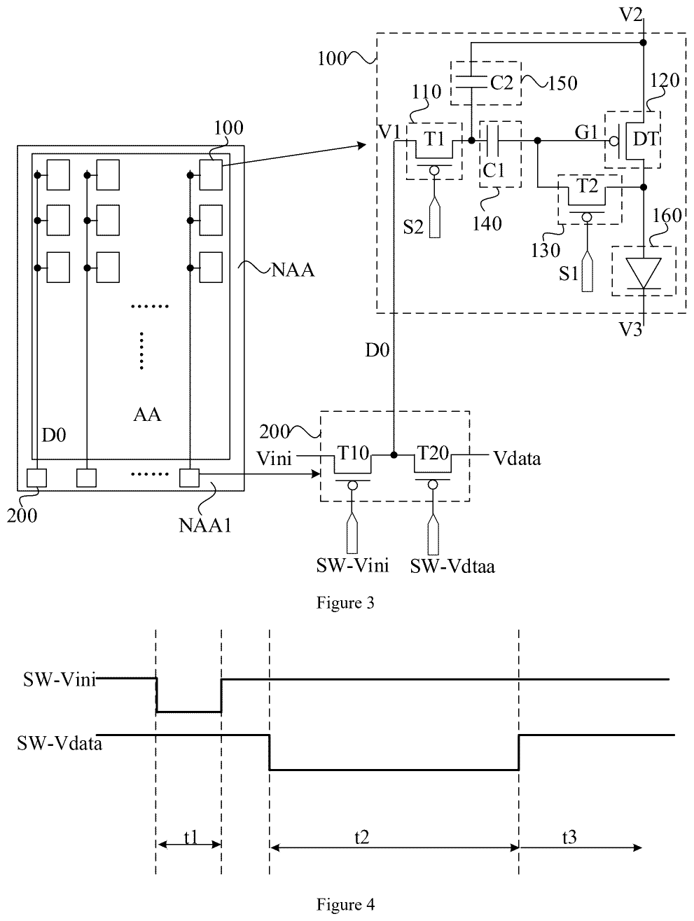

FIG. 2 is a schematic diagram of a structure of another display panel according to an embodiment of the present application. FIG. 3 is a schematic diagram of a structure of another display panel according to an embodiment of the present application. Referring to FIG. 2 and FIG. 3, in one embodiment, the display panel further includes a first voltage selection module 200. The first voltage selection module 200 includes a first input terminal IN1, a second input terminal IN2, a first control terminal SW−Vini, a second control terminal SW−Vdata, and a first output terminal. The first output terminal is electrically connected to the first voltage input terminal V1. The first input terminal is connected to an initial voltage Vini, and the second input terminal is connected to a data voltage Vdata.

The first voltage selection module 200 is configured to: transmit the initial voltage Vini to the first voltage input terminal V1 in a compensation phase in response to a first control signal at the first control terminal SW−Vini; and transmit the data voltage Vdata to the first voltage input terminal V1 in a data writing phase in response to a second control signal at the second control terminal SW−Vdata.

Specifically, in the compensation phase, the first control signal inputted to the first control terminal SW−Vini is a conduction control signal, and the first input terminal and the first output terminal are conducted. The initial voltage Vini may be transmitted to the first voltage input terminal V1 through a connection path between the first input terminal and the first output terminal. In the data writing phase, the second control signal inputted to the second control terminal SW−Vdata is a conduction control signal, and the second input terminal and the first output terminal are conducted. The data voltage Vdata may be transmitted to the first voltage input terminal V1 through a connection path between the second input terminal and the first output terminal.

Referring to FIG. 2 and FIG. 3, in one embodiment, the first voltage selection module 200 may include a first transistor T10 and a second transistor T20. A gate of the first transistor T10 is used as the first control terminal SW−Vini of the first voltage selection module 200, a first electrode of the first transistor T10 is used as the first input terminal of the first voltage selection module 200, and a second electrode of the first transistor T10 is used as the first output terminal of the first voltage selection module 200. A gate of the second transistor T20 is used as the second control terminal SW−Vdata of the first voltage selection module 200, a first electrode of the second transistor T20 is used as the second input terminal of the first voltage selection module 200, and a second electrode of the second transistor T20 is used as the first output terminal of the first voltage selection module 200.

Still referring to FIG. 2, in a part of embodiments of the present application, each pixel circuit 100 includes one first voltage selection module 200. That is, the first voltage selection module 200 is provided in an active area AA, and the first voltage selection module 200 is included in the pixel circuit 100, and an increase in a bezel width of the display panel caused by providing the first voltage selection module 200 is avoided. This helps implement a narrow bezel.

Referring to FIG. 3, in another part of the embodiments of the present application, the first voltage selection module 200 is provided in a non-active area NAA of the display panel, the display panel further includes data lines D0, the first output terminal of the first voltage selection module 200 is electrically connected to the data line D0 in a one-to-one correspondence, and each data line D0 is connected to first voltage input terminals V1 of one column of pixel circuits 100.

In this embodiment, the first voltage selection module 200 is provided in the non-active area NAA, and each first voltage selection module 200 may be configured to control voltages of the first voltage input terminals V1 of one column of pixel circuits 100. Specifically, for one column of pixel circuits 100 to which the first voltage selection module 200 is connected, in compensation phases of the pixel circuits 100, a conduction control signal is inputted to the first control terminal SW−Vini of the first voltage selection module 200, and the first input terminal and the first output terminal of the first voltage selection module 200 are conducted, to transmit the initial voltage Vini to the data line D0 through a connection path between the first input terminal and the first output terminal. The data line D0 can transmit the initial voltage Vini to the first voltage input terminals V1 of one column of pixel circuits 100 to which the data line D0 is correspondingly connected. Compensation phases of the same column of pixel circuits 100 may be performed simultaneously. For one column of pixel circuits 100 to which the first voltage selection module 200 is connected, in data writing phases of the pixel circuits 100, a conduction control signal is inputted to the second control terminal SW−Vdata of the first voltage selection module 200, and the second input terminal and the first output terminal of the first voltage selection module 200 are conducted, to transmit the data voltage Vdata to the data line D0 through a connection path between the second input terminal and the first output terminal. The data line D0 can transmit the data voltage Vdata to the first voltage input terminals V1 of one column of pixel circuits 100 to which the data line D0 is correspondingly connected. Data writing phases of all rows of pixel circuits 100 are performed in sequence at different times. In the data writing phase of each pixel circuit 100, the data voltage Vdata at the first voltage input terminal V1 may be transmitted to the first terminal of the coupling module 140 through the data writing module 110. The first voltage selection module 200 is provided in the non-active area NAA of the display panel, and the pixel circuit 100 in the active area AA may include a small number of circuit modules, thereby helping improve the transmittance of the display panel.

Still referring to FIG. 3, the display panel includes an active area AA and a non-active area NAA. The non-active area NAA includes a defined bezel area NAA1, and the first voltage selection module 200 is located in the defined bezel area NAA1. The defined bezel area NAA1 includes a lead-out line that leads out the data voltage Vdata from a driving chip. The lead-out line is electrically connected to the data line DO.

Specifically, the non-active area NAA may include bezel areas. For example, for the display panel shown in FIG. 3, the non-active area NAA may include an upper bezel area, a lower bezel area, a left bezel area, and a right bezel area. The defined bezel area NAA1 is a bezel area including the lead-out line that leads out the data voltage Vdata from the driving chip. For the display panel shown in FIG. 3, the defined bezel area NAA1 may be the lower bezel area. The driving chip may be provided in the lower bezel area or on a non-light-emitting side of the display panel. A large number of leads and circuit structures, such as a power supply that supplies the initial voltage Vini (or a lead connected to the power supply that supplies the initial voltage Vini) and the above lead-out line that leads out the data voltage Vdata from the driving chip, need to be provided in the defined bezel area NAA1 of the display panel. Therefore, the first voltage selection module 200 is provided in the defined bezel area NAA1 of the display panel, and the first voltage selection module 200 is more conveniently connected to the power supply that supplies the initial voltage Vini, and the first voltage selection module 200 is more conveniently connected to the driving chip that provides the data voltage Vdata. In addition, because a large number of leads and circuit structures need to be provided in the defined bezel area NAA1 of the display panel, the defined bezel area NAA1 is defined with a specific width, to provide the first voltage selection module 200 in the defined bezel area NAA1. This, although increasing the width of the defined bezel area NAA1, generates less impact on user experience compared with providing the first voltage selection module 200 in a bezel area with a small width other than the defined bezel area NAA1.

FIG. 4 is a schematic diagram of a type of driving timing for a display panel according to an embodiment of the present application. The driving timing may be used to drive the display panels shown in FIG. 2 and FIG. 3. The driving timing shown in FIG. 4 shows only driving signals for the first voltage selection module (that is, driving signals for the first control terminal SW−Vini and the second control terminal SW−Vdata) and a corresponding situation in which the first transistor T10 and the second transistor T20 in the first voltage selection module 200 are P-type transistors. Referring to FIG. 2 to FIG. 4, an operating process of the pixel circuit in the display panel includes a compensation phase t1, a data writing phase t2, and a light emission phase t3.

In the pixel circuit 100 of the display panels shown in FIG. 2 and FIG. 3, operation processes of the data writing module 110, the driving module 120, the compensation module 130, the coupling module 140, the storage module 150, and the light-emitting module 160 in the compensation phase t1, the data writing phase t2, and the light emission phase t3 are the same as the operation process of the pixel circuit 100 of the display panel shown in FIG. 1. Details are not described herein again.

Because the first voltage selection module 200 is added to the display panels shown in FIG. 2 and FIG. 3, an operation process of the first voltage selection module 200 is described below. In the compensation phase t1, the first control signal inputted to the first control terminal SW−Vini of the first voltage selection module 200 is a low-level signal, and the first transistor T10 is conducted, to transmit the initial voltage Vini to the first voltage input terminal V1. In the data writing phase t2, the second control signal inputted to the second control terminal SW−Vdata of the first voltage selection module 200 is a low-level signal, and the second transistor T20 is conducted, to transmit the data voltage Vdata to the first voltage input terminal V1. In the light emission phase t3, the first control signal at the first control terminal SW−Vini and the second control signal at the second control terminal SW−Vdata are both high-level signals, and the first transistor T10 and the second transistor T20 are both cut off.

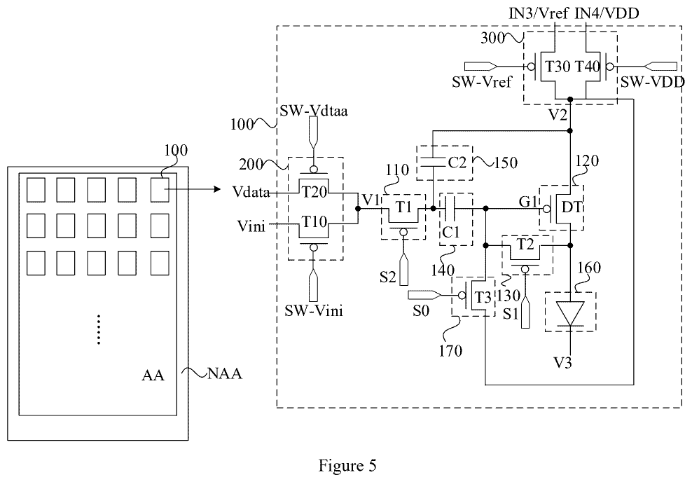

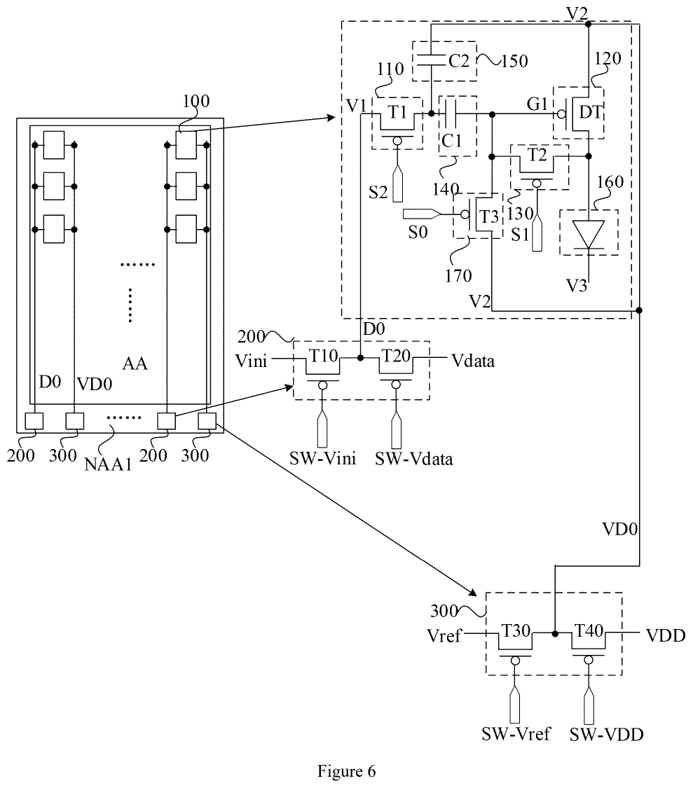

FIG. 5 is a schematic diagram of a structure of another display panel according to an embodiment of the present application. FIG. 6 is a schematic diagram of a structure of another display panel according to an embodiment of the present application. Referring to FIG. 5 and FIG. 6, in one embodiment, the pixel circuit 100 further includes a reset module 170. An input terminal of the reset module 170 is electrically connected to the second voltage input terminal V2, and an output terminal of the reset module 170 is electrically connected to the control terminal of the driving module 120. The reset module 170 is configured to transmit to the control terminal of the driving module 120 in a first reset phase, a reset voltage inputted from the second voltage input terminal V2. The compensation module 130 is further configured to be conducted in the first reset phase to transmit, to the second terminal of the driving module 120, the reset voltage transmitted by the reset module 170, where the first reset phase is performed before the compensation phase.

In the first reset phase, the reset module 170 is conducted. The second voltage input terminal V2 inputs the reset voltage. The reset voltage is transmitted to the control terminal of the driving module 120 through the reset module 170 that is conducted, to reset the control terminal of the driving module 120. The pixel circuit 100 is provided to include the reset module 170, the reset module 170 resets the control terminal of the driving module 120 in the first reset phase, and an appropriate reset voltage is set. In this way, it can be ensured that the driving module 120 is conducted based on the reset voltage at the control terminal and the voltage at the first terminal of the driving module 120 in a compensation phase performed after the first reset phase, and that the threshold voltage of the driving module 120 is compensated for when the compensation module 130 is conducted in the compensation phase, to avoid a case in which the driving module 120 fails to be conducted because a previous frame of data on the control terminal of the driving module 120 is not cleared, and consequently the compensation phase cannot be normally performed. A magnitude of the reset voltage may be set based on a type of the driving transistor included in the driving module 120 and a magnitude of the voltage inputted from the second voltage input terminal to the first terminal of the driving module 120 in the first reset phase. The reset voltage is required to ensure that the driving module 120 can be conducted in the first reset phase. The reset module 170 may include a reset transistor. A gate of the reset transistor is used as a control terminal of the reset module 170, a first electrode of the reset transistor is used as a first terminal of the reset module 170, and a second electrode of the reset transistor is used as a second terminal of the reset module 170.

On the basis of the above embodiments, the driving module 120 is further configured to transmit the voltage at the first terminal of the driving module 120 to the second terminal of the driving module 120 in a second reset phase. The second reset phase is performed between the compensation phase and the data writing phase.

Specifically, after the compensation phase is completed, the driving module 120 is in a critical on/off state. That is, in the second reset phase, the driving module 120 is in the critical on/off state, and the driving module 120 may transmit the voltage at the first terminal to the second terminal of the driving module 120, to reset a first terminal of the light-emitting module 160. This ensures that the first terminal of the light-emitting module 160 is fully reset.

For the display panels shown in FIG. 5 and FIG. 6, when the operation process of the pixel circuit 100 includes the second reset phase, it needs to be ensured that the light-emitting module 160 does not emit light after the voltage at the first terminal of the driving transistor is transmitted to the second terminal of the driving transistor in the second reset phase, to avoid an adverse impact of light emission of the light-emitting module 160 in a phase other than the light emission phase on a display effect.

It should be further noted that, in the second reset phase, the compensation module 130 is cut off, and a potential at the second terminal of the driving module 120 is no longer transmitted to the control terminal of the driving module 120.

Still referring to FIG. 5 and FIG. 6, in one embodiment, the display panel further includes a second voltage selection module 300. The second voltage selection module 300 includes a third input terminal IN3, a fourth input terminal IN4, a third control terminal SW−Vref, a fourth control terminal SW−VDD, and a second output terminal. The second output terminal is electrically connected to the second voltage input terminal V2. The third input terminal is connected to a reset voltage Vref. The fourth input terminal is connected to a first power supply voltage VDD.

The second voltage selection module 300 is configured to: transmit the reset voltage Vref to the second voltage input terminal V2 in the first reset phase in response to a third control signal at the third control terminal SW−Vref, and transmit the first power supply voltage VDD to the second voltage input terminal V2 in the light emission phase in response to a fourth control signal at the fourth control terminal SW−VDD.

Specifically, in the first reset phase, the third control signal inputted to the third control terminal SW−Vref is a conduction control signal, and the third input terminal and the second output terminal are conducted. The reset voltage Vref may be transmitted to the second voltage input terminal V2 through a connection path between the third input terminal and the second output terminal. In the light emission phase, the fourth control signal inputted to the fourth control terminal SW−VDD is a conduction control signal, and the fourth input terminal and the second output terminal are conducted. The first power supply voltage VDD may be transmitted to the second voltage input terminal V2 through a connection path between the fourth input terminal and the second output terminal.

Referring to FIG. 5 and FIG. 6, in one embodiment, the second voltage selection module 300 may include a third transistor T30 and a fourth transistor T40. A gate of the third transistor T30 is used as the third control terminal SW−Vref of the second voltage selection module 300, a first electrode of the third transistor T30 is used as the third input terminal of the second voltage selection module 300, and a second electrode of the third transistor T30 is used as the second output terminal of the second voltage selection module 300. A gate of the fourth transistor T40 is used as the fourth control terminal SW−VDD of the second voltage selection module 300, a first electrode of the fourth transistor T40 is used as the fourth input terminal of the second voltage selection module 300, and a second electrode of the fourth transistor T40 is used as the second output terminal of the second voltage selection module 300.

For the display panels shown in FIG. 5 and FIG. 6, the second voltage selection module 300 may transmit the first power supply voltage VDD to the second voltage input terminal V2 in the compensation phase in response to the fourth control signal at the fourth control terminal SW−VDD. In the compensation phase, the fourth control signal inputted to the fourth control terminal SW−VDD is a conduction control signal, and the fourth input terminal and the second output terminal are conducted. The first power supply voltage VDD may be transmitted to the second voltage input terminal V2 through a connection path between the fourth input terminal and the second output terminal. In this case, in the compensation phase, the driving module 120 and the compensation module 130 transmit the first power supply voltage VDD to the control terminal of the driving module 120, to compensate for the threshold voltage of the driving module 120. In this way, a structure of the second voltage selection module 300 is simple, high transmittance of the display panel can be ensured when the second voltage selection module 300 is provided in the active area AA, and an excessively large width of the bezel of the display panel is avoided when the second voltage selection module 300 is provided in the non-active area NAA. However, the first power supply voltage VDD is a voltage that may cause the light-emitting module 160 to emit light in response to directly reaching the first terminal of the light-emitting module 160 through the driving module 120 when the driving module 120 is conducted. Therefore, in order to prevent light emission in a phase other than the light emission phase, a switch needs to be provided between the first terminal of the light-emitting module 160 and the second terminal of the driving module 120 to control a conduction state between the driving module 120 and the first terminal of the light-emitting module 160, or voltages connected to the second terminal of the light-emitting module 160 in the light emission phase and in a phase other than the light emission phase are set to be different.

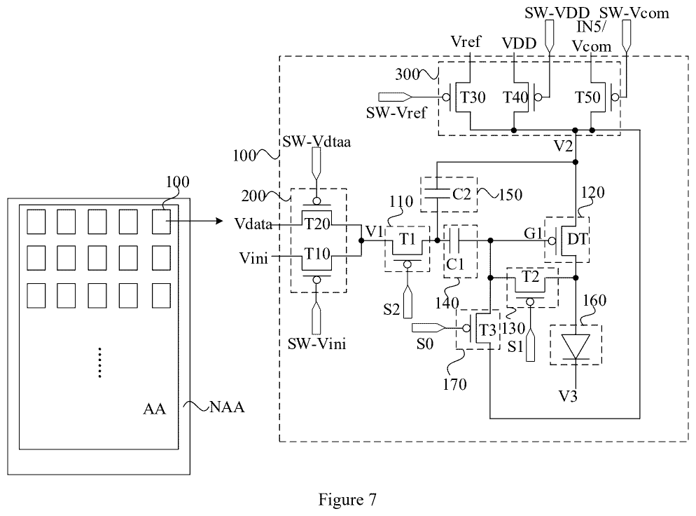

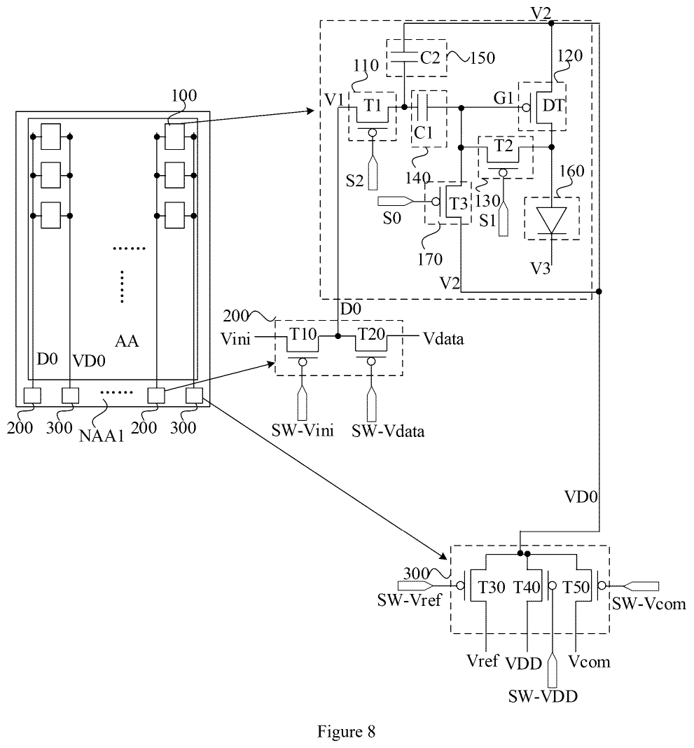

FIG. 7 is a schematic diagram of a structure of another display panel according to an embodiment of the present application. FIG. 8 is a schematic diagram of a structure of another display panel according to an embodiment of the present application. Referring to FIG. 7 and FIG. 8, the second voltage selection module 300 further includes a fifth input terminal IN5 and a fifth control terminal SW−Vcom. The fifth input terminal is connected to a compensation voltage Vcom. The compensation voltage Vcom is less than the first power supply voltage VDD. The second voltage selection module 300 is further configured to transmit the compensation voltage Vcom to the second voltage input terminal V2 in the compensation phase in response to a control signal at the fifth control terminal SW−Vcom.

Still referring to FIG. 7 and FIG. 8, the second voltage selection module 300 further includes a fifth transistor T50. A gate of the fifth transistor T50 is used as the fifth control terminal SW−Vcom of the second voltage selection module 300, a first electrode of the fifth transistor T50 is used as the fifth input terminal of the second voltage selection module 300, and a second electrode of the fifth transistor T50 is used as the second output terminal of the second voltage selection module 300.

Different from the display panel shown in FIG. 5 and FIG. 6, when the second voltage selection module 300 has the structure shown in FIG. 7 and FIG. 8, in the compensation phase, a fifth control signal inputted to the fifth control terminal SW−Vcom is a conduction control signal, and the fifth input terminal and the second output terminal of the second voltage selection module 300 are conducted in the compensation phase. The compensation voltage Vcom is transmitted to the second voltage input terminal V2 through a connection path between the fifth input terminal and the second output terminal. In this case, in the compensation phase, the driving module 120 and the compensation module 130 transmit the compensation voltage Vcom to the control terminal of the driving module 120, to compensate for the threshold voltage of the driving module 120. In this embodiment, the compensation voltage Vcom is less than the first power supply voltage VDD. In one embodiment, the compensation voltage Vcom is a voltage that does not cause the light-emitting module 160 to emit light when reaching the second terminal of the driving module 120 through the first terminal of the driving module 120 and reaching the first terminal of the light-emitting module 160 through the second terminal of the driving module 120. In this case, in the compensation phase, even if no switch is provided between the second terminal of the driving module 120 and the first terminal of the light-emitting module 160 in the pixel circuit 100 to control the conduction state between the driving module 120 and the first terminal of the light-emitting module 160, the light-emitting module 160 does not emit light in a phase other than the light emission phase. In one embodiment, even if voltages connected to the second terminal of the light-emitting module 160 in the light emission phase and in a phase other than the light emission phase are set to be the same, the light-emitting module 160 does not emit light in the phase other than the light emission phase.

Still referring to FIG. 7, in a part of the embodiments of the present application, each pixel circuit 100 includes one second voltage selection module 300. That is, the second voltage selection module 300 is provided in the active area AA, and the second voltage selection module 300 is included in the pixel circuit 100.

Referring to FIG. 8, in another part of the embodiments of the present application, the second voltage selection module 300 is provided in the non-active area NAA of the display panel, and the display panel further includes first power supply traces VD0. The second output terminal of the second voltage selection module 300 is electrically connected to the first power supply trace VD0 in a one-to-one correspondence. Each first power supply trace VD0 is connected to second voltage input terminals V2 of one column of pixel circuits 100.

In this embodiment, the second voltage selection module 300 is provided in the non-active area NAA, and each second voltage selection module 300 may be configured to control voltages of the second voltage input terminals V2 of one column of pixel circuits 100. Specifically, for one column of pixel circuits 100 to which the second voltage selection module 300 is connected, in first reset phases of the pixel circuits 100, a conduction control signal is inputted to the third control terminal SW−Vref of the second voltage selection module 300, and the third input terminal and the second output terminal of the second voltage selection module 300 are conducted, to transmit the reset voltage Vref to the first power supply trace VD0 through a connection path between the third input terminal and the second output terminal. The first power supply trace VD0 can transmit the reset voltage Vref to the second voltage input terminals V2 of one column of pixel circuits 100 to which the first power supply trace VD0 is correspondingly connected. First reset phases of the same column of pixel circuits 100 may be performed simultaneously. For one column of pixel circuits 100 to which the second voltage selection module 300 is connected, in light emission phases of the pixel circuits 100, a conduction control signal is inputted to the fourth control terminal SW−VDD of the second voltage selection module 300, and the fourth input terminal and the second output terminal of the second voltage selection module 300 are conducted, to transmit the first power supply voltage VDD to the first power supply trace VD0 through a connection path between the fourth input terminal and the second output terminal. The first power supply trace VD0 can transmit the first power supply voltage VDD to the second voltage input terminals V2 of one column of pixel circuits 100 to which the first power supply trace VD0 is correspondingly connected. Light emission phases of all rows of pixel circuits 100 may be performed simultaneously. A manner in which the second voltage selection module 300 supplies the first power supply voltage VDD to the second voltage input terminal V2 in the compensation phase may be implemented by inputting a conduction control signal to the fourth control terminal SW−VDD of the second voltage selection module 300 in the compensation phase. Compensation phases of the same column of pixel circuits may be performed simultaneously.

The second voltage selection module 300 is provided in the non-active area NAA of the display panel, and the pixel circuit 100 in the active area AA may include a small number of circuit modules, thereby helping improve the transmittance of the display panel.

Still referring to FIG. 8, in one embodiment, the display panel includes an active area AA and a non-active area NAA. The non-active area NAA includes a defined bezel area NAA1, and the second voltage selection module 300 is located in the defined bezel area NAA1. The defined bezel area NAA1 includes a lead-out line that leads out the data voltage Vdata from the driving chip. The lead-out line is electrically connected to the data line D0 of the display panel.

Specifically, the non-active area NAA may include bezel areas. For example, for the display panel shown in FIG. 8, the non-active area NAA may include an upper bezel area, a lower bezel area, a left bezel area, and a right bezel area. The defined bezel area NAA1 is a bezel area including the lead-out line that leads out the data voltage Vdata from the driving chip. For the display panel shown in FIG. 8, the defined bezel area NAA1 may be the lower bezel area. The driving chip may be provided in the lower bezel area or on a non-light-emitting side of the display panel. A large number of leads and circuit structures, such as a power supply that supplies the reset voltage Vref (or a lead connected to the power supply that supplies the reset voltage Vref), a power supply that supplies the first power supply voltage VDD (or a lead connected to the power supply that supplies the first power supply voltage VDD), and the above lead-out line that leads out the data voltage Vdata from the driving chip, need to be provided in the defined bezel area NAA1 of the display panel. Therefore, the second voltage selection module 300 is provided in the defined bezel area NAA1 of the display panel, and the second voltage selection module 300 is more conveniently connected to the power supply that supplies the reset voltage Vref, and the second voltage selection module 300 is more conveniently connected to the power supply that supplies the first power supply voltage VDD. In addition, because a large number of leads and circuit structures need to be provided in the defined bezel area NAA1 of the display panel, the defined bezel area NAA1 is defined with a specific width, to provide the second voltage selection module 300 in the defined bezel area NAA1. This, although increasing the width of the defined bezel area NAA1, generates less impact on user experience compared with providing the second voltage selection module 300 in a bezel area with a small width other than the defined bezel area NAA1.

Still referring to FIG. 7 and FIG. 8, the display panel further includes first gate control lines S0. The first gate control line S0 is connected to the control terminal of the reset module 170. Still referring to FIG. 1 to FIG. 8, the display panel further includes second gate control lines S1 and scan lines S2. In the pixel circuit 100, the data writing module 110 includes a data writing transistor T1. A gate of the data writing transistor T1 is used as a control terminal of the data writing module 110 and is connected to the scan line S2 in the display panel, a first electrode of the data writing transistor T1 is used as a first terminal of the data writing module 110 and is connected to the first voltage input terminal V1, and a second electrode of the data writing transistor T1 is used as a second terminal of the data writing module 110 and is connected to the first terminal of the coupling module 140. The coupling module 140 may include a first capacitor C1, and the storage module 150 may include a second capacitor C2. The driving module 120 includes a driving transistor DT, and the compensation module 130 includes a compensation transistor T2. A gate of the compensation transistor T2 is used as a control terminal of the compensation module 130 and is connected to the second gate control line S1 in the display panel. The light-emitting module 160 may include a light-emitting device. The light-emitting device may be an organic light-emitting device or an inorganic light-emitting device, which is not specifically limited in this embodiment.

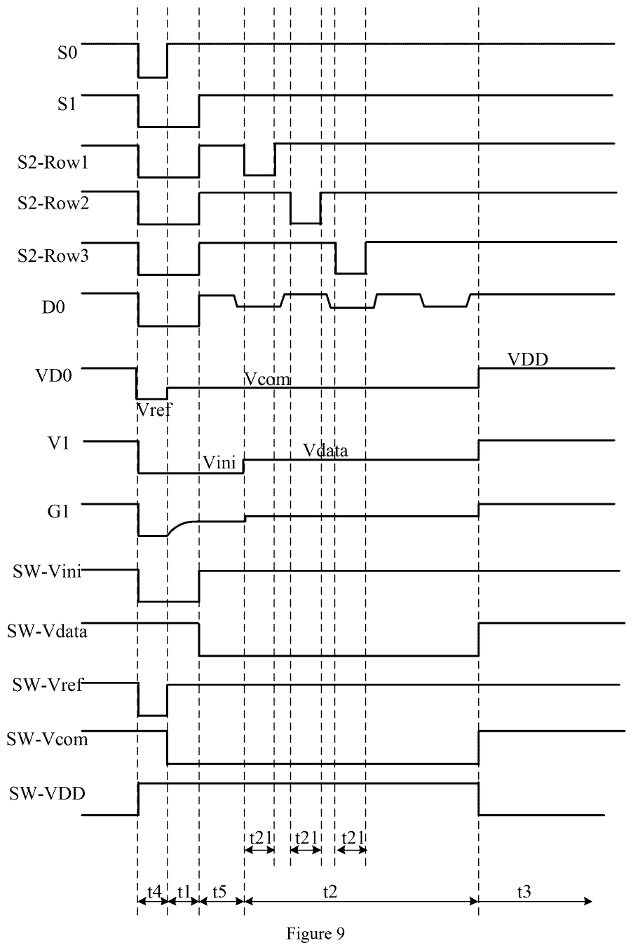

A detailed operation process of the display panels shown in FIG. 7 and FIG. 8 is described below. FIG. 9 is a schematic diagram of another type of driving timing for a display panel according to an embodiment of the present application. The driving timing may be used to drive the display panels shown in FIG. 7 and FIG. 8. An example in which the transistors shown in FIG. 7 and FIG. 8 are all P-type transistors is used for description. Referring to FIG. 7 to FIG. 9, an operation process of the display panel includes a first reset phase t4, a compensation phase t1, a second reset phase t5, a data writing phase t2, and a light emission phase t3. The data writing phase t2 of the display panel may include data writing phases of all rows of pixel circuits. The data writing phase of each row of pixel circuits is denoted as a data writing sub-phase t21.

In the first reset phase t4, the first control signal inputted to the first control terminal SW−Vini of the first voltage selection module 200 is a low-level signal, and the first transistor T10 is conducted, to transmit the initial voltage Vini to the first voltage input terminal V1. A signal on the scan line S2 is a low-level signal, and the data writing transistor T1 is conducted, to transmit the initial voltage Vini of the first voltage input terminal to the first terminal of the coupling module 140. The third control signal inputted to the third control terminal SW−Vref of the second voltage selection module 300 is a low-level signal, and the third transistor T30 is conducted, to transmit the reset voltage Vref to the second voltage input terminal V2. A signal on the first gate control line S0 is a low-level signal, and the reset transistor T3 is conducted, to transmit the reset voltage Vref of the second voltage input terminal V2 to the control terminal of the driving module 120, thereby resetting the control terminal of the driving module 120. A signal on the second gate control line S1 is a low-level signal, and the compensation transistor T2 is conducted, to transmit the reset voltage Vref to the second terminal of the driving module 120 through the reset transistor T3 and the compensation transistor T2, thereby resetting the second terminal of the driving module 120 and resetting an anode of the light-emitting device. The second terminal of the driving module 120 may be a drain of the driving transistor DT, and the first terminal of the driving module 120 may be a source of the driving transistor DT.

In the compensation phase t1, the first control signal inputted to the first control terminal SW−Vini of the first voltage selection module 200 is a low-level signal, and the first transistor T10 is conducted, to transmit the initial voltage Vini to the first voltage input terminal V1. The signal on the scan line S2 is a low-level signal, and the data writing transistor T1 is conducted, to transmit the initial voltage Vini of the first voltage input terminal to the first terminal of the coupling module 140. The fifth control signal inputted to the fifth control terminal SW−Vcom of the second voltage selection module 300 is a low-level signal, and the fifth transistor T50 is conducted, to transmit the compensation voltage Vcom to the second voltage input terminal V2. The signal on the second gate control line S1 is a low-level signal, and the compensation transistor T2 is conducted. In the compensation phase t1, the driving transistor DT is conducted based on potentials at a control terminal and a first terminal thereof, and the compensation voltage Vcom is transmitted to the control terminal of the driving transistor DT through the driving transistor DT and the compensation transistor T2, until a potential at a gate of the driving transistor DT is equal to Vcom+Vth, where Vth is a threshold voltage of the driving transistor DT. In the compensation phase t1, the signal on the first gate control line S0 is a high-level signal, and the reset transistor T3 is cut off.

In the second reset phase t5, the signals on the first gate control line S0, the second gate control line S1, and the scan line S2 are all high-level signals, and the reset transistor T3, the compensation transistor T2, and the data writing transistor T1 are all cut off. The second voltage selection module 300 operates in the same state as that in the compensation phase t1. Therefore, the voltage of the second voltage input terminal V2 is still the compensation voltage Vcom. The driving transistor DT is in a critical on/off state, and the compensation voltage Vcom is further transmitted to the anode of the light-emitting device, to reset the anode of the light-emitting device again.

In the data writing phase t2, the second control signal inputted to the second control terminal SW−Vdata of the first voltage selection module 200 is a low-level signal, and the second transistor T20 is conducted, to transmit the data voltage Vdata to the first voltage input terminal V1. The data writing phase t2 of the display panel includes n data writing sub-phases t21, where n is equal to the number of rows of the pixel circuits 100 in the display panel. Each data writing sub-phase t21 corresponds to the data writing phase t2 of one row of pixel circuits 100. In FIG. 9, S2−Row1 represents a scan line to which control terminals of data writing modules 110 of a first row of pixel circuits 100 in the display panel are connected, S2−Row2 represents a scan line to which control terminals of data writing modules 110 of a second row of pixel circuits 100 in the display panel are connected, and S2−Row3 represents a scan line to which control terminals of data writing modules 110 of a third row of pixel circuits 100 in the display panel are connected. The display panel may include w scan lines S2. Each scan line S2 is correspondingly connected to one row of pixel circuits 100. In the data writing phase t2 of the display panel, in the display panel, signals on the scan line S2−Row1 to which the control terminals of the data writing modules 110 of the first row of pixel circuits 100 are connected, the scan line S2−Row2 to which the control terminals of the data writing modules 110 of the second row of pixel circuits 100 are connected, the scan line S2-Row3 to which the control terminals of the data writing modules 110 of the third row of pixel circuits 100 are connected, . . . , and the scan line S2 to which control terminals of data writing modules 110 of a w^{th} row of pixel circuits 100 are connected are low-level pulses in sequence, and the data writing modules 110 of the first row of pixel circuits 100 to the data writing modules 110 of the w^{th} row of pixel circuits 100 are conducted in sequence, to write the data voltage Vdata to the pixel circuits 100 row by row. The data writing transistor T1 transmits the data voltage Vdata to the first terminal of the coupling module 140, and the first terminal of the coupling module 140 jumps from the initial voltage Vini to the data voltage Vdata. The potential at the first terminal of the coupling module 140 changes from the initial voltage Vini to the data voltage Vdata, with a voltage change at the first terminal of the coupling module 140 being ΔV1=Vdata−Vini. In this case, a voltage at the gate of the driving transistor DT changes correspondingly, with a specific change being

ΔV2=k*(Vdata−Vini),

where

k=C10/(C10+Cother_g),

C10 is a capacitance value of the first capacitor C1, and Cother_g is a capacitance value of another capacitor of the gate. In this case, a potential at the gate of the driving transistor DT is Vcom+Vth+k*(Vdata−Vini).

In the light emission phase t3, the first control signal at the first control terminal SW-Vini of the first voltage selection module 200 and the second control signal at the second control terminal SW−Vdata of the first voltage selection module 200 are both high-level signals, and the first transistor T10 and the second transistor T20 are both cut off. The fourth control signal at the fourth control terminal SW−VDD of the second voltage selection module 300 is a low-level signal, and the fourth transistor T40 is conducted, to transmit the first power supply voltage VDD to the second voltage input terminal. The driving transistor DT is conducted based on the voltage at the gate and the first power supply voltage VDD, to generate a driving current to drive the light-emitting device to emit light. Because a voltage on the first power supply trace jumps from the compensation voltage Vcom to the first power supply voltage VDD, and the voltage at the second voltage input terminal V2 jumps from the compensation voltage Vcom to the first power supply voltage VDD, with a voltage change at the second voltage input terminal V2 being ΔV3=VDD-Vcom, the voltage at the first terminal of the coupling module 140 correspondingly changes to Vdata+k1*(VDD−Vcom), and the voltage at the first terminal of the coupling module 140 changes to k1*(VDD−Vcom), where

k1=C2/(C1+C2+Cother_n1),

and Cother_n1 represents a capacitance value of another capacitor of the first terminal of the coupling module 140, and the gate of the driving transistor DT is coupled to Vcom+Vth+k*(Vdata−Vini)+k*k1*(VDD−Vcom). Therefore, in the light emission phase t3,

Vgs−Vth=Vcom+Vth+k*(Vdata−Vini)+k*k1*(VDD−Vcom)−VDD−Vth,

where Vgs represents a voltage difference between the gate and the first electrode of the driving transistor DT. Therefore, the threshold voltage of the driving transistor DT can be compensated for through the structure of the pixel circuit 100 in the display panel in this embodiment.

In a part of embodiments of the present application, k and k1 are set to 100% or to be close to 100% (for example, 95%-99%), and the above formula is approximated as

Vgs−Vth=Vcom+Vth+(Vdata−Vini)+(VDD−Vcom)−VDD−Vth=Vdata−Vini.

In the light emission phase t3, a current of the driving transistor DT is

I=½μ*Cox*W/L*(Vdata−Vini)²,

which finally compensates for factors VDD, Vcom, and Vth in a light-emitting current.

μ is a carrier mobility of the driving transistor DT, Cox is a gate oxide capacitance per unit area of the driving transistor DT, and W/L is a channel width-to-length ratio of the driving transistor DT.

Because setting k and k1 to 1 requires large capacitance values and areas of C1 and C2, in another part of the embodiments of the present application, k and k1 may be set to 0.5-1.

For the display panels shown in FIG. 7 and FIG. 8, a voltage inputted from a third voltage input terminal V3 to which the second terminal of the light-emitting module is connected may be a fixed voltage.

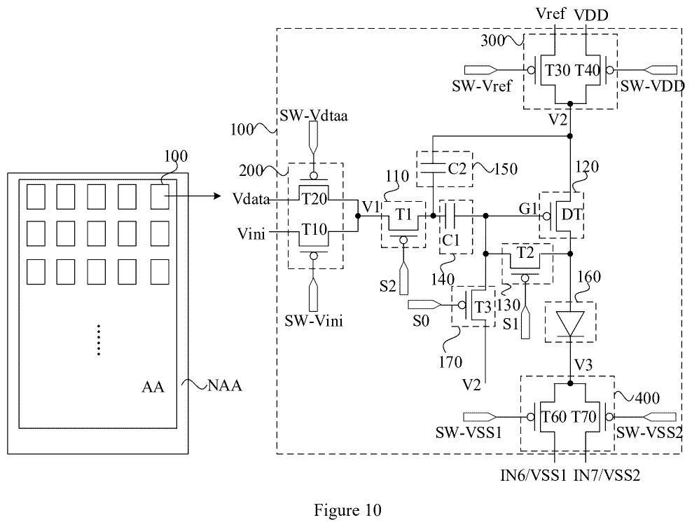

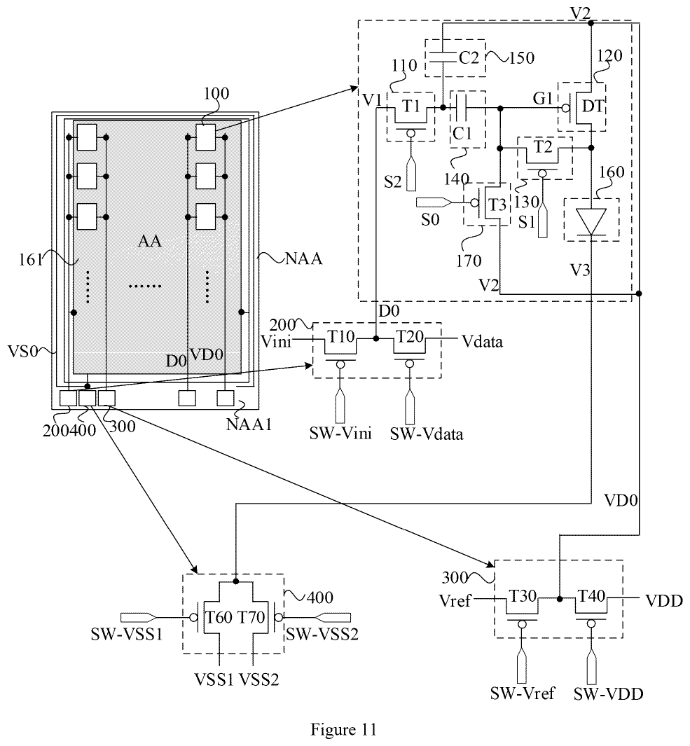

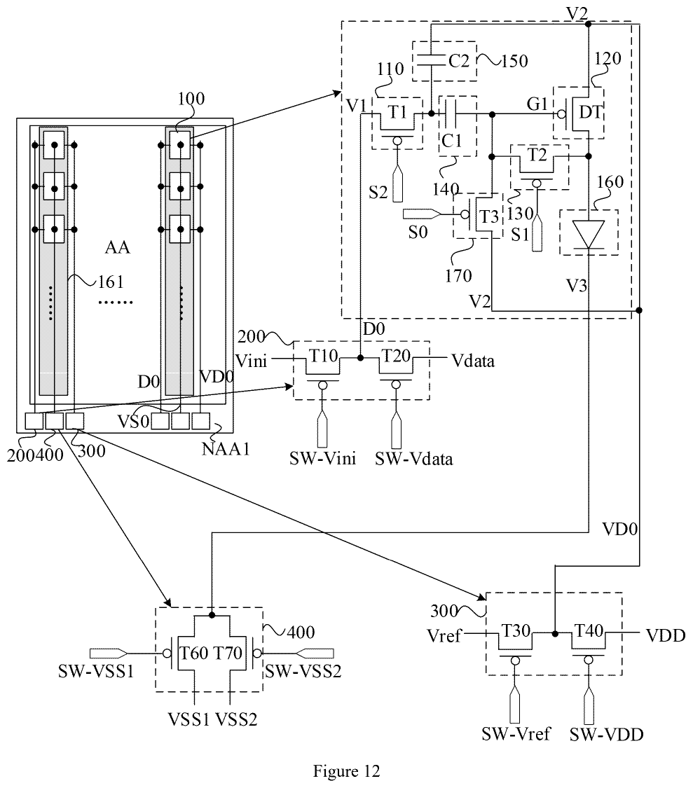

FIG. 10 is a schematic diagram of a structure of another display panel according to an embodiment of the present application. FIG. 11 is a schematic diagram of a structure of still another display panel according to an embodiment of the present application. FIG. 12 is a schematic diagram of a structure of yet another display panel according to an embodiment of the present application. Referring to FIG. 10 to FIG. 12, in one embodiment, the second terminal of the driving module 120 is connected to the first terminal of the light-emitting module 160, and the second terminal of the light-emitting module 160 is connected to the third voltage input terminal V3. The display panel further includes a third voltage selection module 400. The third voltage selection module 400 includes a sixth input terminal IN6, a seventh input terminal IN7, a sixth control terminal SW−VSS1, a seventh control terminal SW−VSS2, and a third output terminal. The third output terminal is electrically connected to the third voltage input terminal V3. The sixth input terminal is connected to a first cathode voltage VSS1, and the seventh input terminal is connected to a second cathode voltage VSS2. The second cathode voltage VSS2 is greater than the first cathode voltage VSS1.

The third voltage selection module 400 is configured to: transmit the second cathode voltage VSS2 to the third voltage input terminal V3 in a phase other than the light emission phase in response to a seventh control signal at the seventh control terminal SW−VSS2; and transmit the first cathode voltage VSS1 to the third voltage input terminal V3 in the light emission phase in response to a sixth control signal at the sixth control terminal SW−VSS1.

Specifically, in the light emission phase, the sixth control signal inputted to the sixth control terminal SW−VSS1 is a conduction control signal, and the sixth input terminal and the third output terminal are conducted. The first cathode voltage VSS1 may be transmitted to the third voltage input terminal V3 through a connection path between the sixth input terminal and the third output terminal. In the phase other than the light emission phase, the seventh control signal inputted to the seventh control terminal SW−VSS2 is a conduction control signal, and the seventh input terminal and the third output terminal are conducted. The second cathode voltage VSS2 may be transmitted to the third voltage input terminal V3 through a connection path between the seventh input terminal and the third output terminal. The second cathode voltage VSS2 is greater than the first cathode voltage VSS1. That is, the voltage transmitted from the third voltage selection module 400 to the third voltage input terminal V3 in the phase other than the light emission phase is greater than the voltage transmitted from the third voltage selection module 400 to the third voltage input terminal V3 in the light emission phase, to ensure that a voltage across the light-emitting module 160 is low in the phase other than the light emission phase, and the light-emitting module 160 does not emit light in the phase other than the light emission phase. However, in the light emission phase, the voltage across the light-emitting module 160 is high, and the light-emitting module 160 can emit light in the light emission phase. For example, in the compensation phase, the first voltage selection module 200 transmits the first power supply voltage VDD to the second voltage input terminal V2. Specifically, the driving module 120 transmits to the second terminal of the driving module 120 in the compensation phase, the first power supply voltage VDD inputted from the second voltage input terminal V2, and the compensation module 130 transmits the voltage at the second terminal of the driving module 120 to the control terminal of the driving module 120 in the compensation phase. Because the third voltage selection module 400 is provided, the light-emitting module 160 can be prevented from emitting light in the compensation phase.

In this embodiment, the display panel is configured to include the third voltage selection module 400, which can avoid the adverse impact of light emission of the light-emitting module 160 in the phase other than the light emission phase (for example, at least one of the first reset phase, the compensation phase, the second reset phase, and the data writing phase) on the display effect.

Referring to FIG. 10 to FIG. 12, in one embodiment, the third voltage selection module 400 may include a sixth transistor T60 and a seventh transistor T70. A gate of the sixth transistor T60 is used as the sixth control terminal SW−VSS1 of the third voltage selection module 400, a first electrode of the sixth transistor T60 is used as the sixth input terminal of the third voltage selection module 400, and a second electrode of the sixth transistor T60 is used as the third output terminal of the third voltage selection module 400. A gate of the seventh transistor T70 is used as the seventh control terminal SW−VSS2 of the third voltage selection module 400, a first electrode of the seventh transistor T70 is used as the seventh input terminal of the third voltage selection module 400, and a second electrode of the seventh transistor T70 is used as the third output terminal of the third voltage selection module 400.

Still referring to FIG. 10, in a part of the embodiments of the present application, each pixel circuit 100 includes one third voltage selection module 400. That is, the third voltage selection module 400 is provided in the active area AA, and the third voltage selection module 400 is included in the pixel circuit 100.

Referring to FIG. 11 and FIG. 12, in a part of the embodiments of the present application, the third voltage selection module 400 is provided in the non-active area NAA of the display panel, and second terminals of light-emitting modules 160 in each column of pixel circuits 100 in the display panel are connected to each other. The display panel further includes a second power supply trace VS0. One end of the second power supply trace VS0 is electrically connected to the third output terminal, and the other end of the second power supply trace VS0 is connected to third voltage input terminals V3 of at least one column of pixel circuits 100.

Referring to FIG. 11, the second terminals of the light-emitting modules 160 in the display panel (the second terminals of the light-emitting modules 160 may be cathodes 161 of the light-emitting devices) are connected to each other. The display panel includes one second power supply trace VS0 that at least partially surrounds the active area AA. The display panel includes one third voltage selection module 400. The third output terminal of the third voltage selection module 400 is connected to the third voltage input terminals V3 of the pixel circuits 100 through the second power supply trace VS0. According to the structure of the display panel shown in FIG. 11, a small number of third voltage selection modules 400 are provided, which occupies a small area of a bezel. This helps implement a narrow bezel. In addition, no second power supply trace VS0 needs to be provided in the active area AA, which helps reduce routing complexity of the active area AA, and in turn helps improve transmittance of the active area AA.

Referring to FIG. 12, the display panel includes second power supply traces VS0 and third voltage selection modules 400 that are electrically connected to the second power supply traces VS0 in a one-to-one correspondence. A third output terminal of the third voltage selection module 400 is connected to third voltage input terminals V3 of at least one column of pixel circuits 100 through the second power supply trace VS0. The second terminals of the light-emitting modules 160 connected to the same second power supply trace VS0 may be connected to each other (specifically through the cathodes 161 of the light-emitting devices included in the light-emitting modules 160), that is, the third voltage input terminals V3 connected to the same second power supply trace VS0 are connected to each other. Through an electrical connection between the second power supply trace VS0 and the third voltage input terminal V3 of at least one pixel circuit 100, a signal on the second power supply trace VS0 can be transmitted to the third voltage input terminals V3 of the at least one column of pixel circuits 100. The structure of the display panel shown in FIG. 12 may make a load to which the third output terminal of each third voltage selection module 400 is connected small, and reduce a requirement on performance of a transistor included in the third voltage selection module 400, and the structure of the display panel can be more easily implemented.

Still referring to FIG. 11 and FIG. 12, the display panel includes an active area AA and a non-active area NAA. The non-active area NAA includes a defined bezel area NAA1, and the third voltage selection module 400 is located in the defined bezel area NAA1. The defined bezel area NAA1 includes a lead-out line that leads out the data voltage Vdata from the driving chip. The lead-out line is electrically connected to the data line D0 of the display panel.

The third voltage selection module 400 is provided in the defined bezel area NAA1 for similar reasons as the first voltage selection module 200 being provided in the defined bezel area NAA1 and the second voltage selection module 300 being provided in the defined bezel area NAA1, which has a similar effect as the first voltage selection module 200 being provided in the defined bezel area NAA1 and the second voltage selection module 300 being provided in the defined bezel area NAA1. Details are not described herein again.

A detailed operation process of the display panels shown in FIG. 10 to FIG. 12 is described below. FIG. 13 is a schematic diagram of another type of driving timing for a display panel according to an embodiment of the present application. The driving timing may be used to drive the display panels shown in FIG. 10 to FIG. 12. An example in which the transistors shown in FIG. 10 to FIG. 12 are all P-type transistors is used for description. Referring to FIG. 11 to FIG. 13, an operation process of the display panel includes a first reset phase t4, a compensation phase t1, a second reset phase t5, a data writing phase t2, and a light emission phase t3. The data writing phase t2 of the display panel may include data writing phases of all rows of pixel circuits. The data writing phase of each row of pixel circuits is denoted as a data writing sub-phase t21.

In the first reset phase t4, the first control signal inputted to the first control terminal SW−Vini of the first voltage selection module 200 is a low-level signal, and the first transistor T10 is conducted, to transmit the initial voltage Vini to the first voltage input terminal V1. The signal on the scan line S2 is a low-level signal, and the data writing transistor T1 is conducted, to transmit the initial voltage Vini of the first voltage input terminal to the first terminal of the coupling module 140. The third control signal inputted to the third control terminal SW−Vref of the second voltage selection module 300 is a low-level signal, and the third transistor T30 is conducted, to transmit the reset voltage Vref to the second voltage input terminal V2. A signal on the first gate control line S0 is a low-level signal, and the reset transistor T3 is conducted, to transmit the reset voltage Vref of the second voltage input terminal V2 to the control terminal of the driving module 120, thereby resetting the control terminal of the driving module 120. A signal on the second gate control line S1 is a low-level signal, and the compensation transistor T2 is conducted, to transmit the reset voltage Vref to the second terminal of the driving module 120 through the reset transistor T3 and the compensation transistor T2, thereby resetting the second terminal of the driving module 120 and resetting an anode of the light-emitting device. The driving module 120 may be a drain of the driving transistor DT, and the first terminal of the driving module 120 may be a source of the driving transistor DT. The sixth control signal inputted to the sixth control terminal SW−VSS1 of the third voltage selection module 400 is at a high level, and the sixth transistor T60 is cut off. The seventh control signal inputted to the seventh control terminal SW−VSS2 of the third voltage selection module 400 is at a low level, and the seventh transistor T70 is conducted, to transmit the second cathode voltage VSS2 to the second terminal of the light-emitting module 160 (that is, to transmit the second cathode voltage VSS2 to the cathode of the light-emitting device), to ensure that a voltage difference between the first terminal and the second terminal of the light-emitting module 160 does not turn on the light-emitting module 160 in the first reset phase t4.

In the compensation phase t1, the first control signal inputted to the first control terminal SW−Vini of the first voltage selection module 200 is a low-level signal, and the first transistor T10 is conducted, to transmit the initial voltage Vini to the first voltage input terminal V1. The signal on the scan line S2 is a low-level signal, and the data writing transistor T1 is conducted, to transmit the initial voltage Vini of the first voltage input terminal to the first terminal of the coupling module 140. The fourth control signal inputted to the fourth control terminal SW−VDD of the second voltage selection module 300 is a low-level signal, and the fourth transistor T40 is conducted, to transmit the first power supply voltage VDD to the second voltage input terminal V2. The signal on the second gate control line S1 is a low-level signal, and the compensation transistor T2 is conducted. In the compensation phase t1, the driving transistor DT is conducted based on the potentials at the control terminal and the first terminal thereof, and the first power supply voltage VDD is transmitted to the control terminal of the driving transistor DT through the driving transistor DT and the compensation transistor T2, until the potential at the gate of the driving transistor DT is equal to VDD+Vth, where Vth is the threshold voltage of the driving transistor DT. In the compensation phase t1, the signal on the first gate control line S0 is a high-level signal, and the reset transistor T3 is cut off. The sixth control signal inputted to the sixth control terminal SW−VSS1 of the third voltage selection module 400 is at a high level, and the sixth transistor T60 is cut off. The seventh control signal inputted to the seventh control terminal SW−VSS2 of the third voltage selection module 400 is at a low level, and the seventh transistor T70 is conducted, to transmit the second cathode voltage VSS2 to the second terminal of the light-emitting module 160 (that is, to transmit the second cathode voltage VSS2 to the cathode of the light-emitting device), to ensure that the voltage difference between the first terminal and the second terminal of the light-emitting module 160 does not turn on the light-emitting module 160 in the compensation phase t1.

In the second reset phase t5, the signals on the first gate control line S0, the second gate control line S1, and the scan line S2 are all high-level signals, and the reset transistor T3, the compensation transistor T2, and the data writing transistor T1 are all cut off. The second voltage selection module 300 operates in the same state as that in the compensation phase t1. Therefore, the voltage of the second voltage input terminal V2 is still the first power supply voltage VDD. The driving transistor DT is in the critical on/off state, and the first power supply voltage VDD is further transmitted to the anode of the light-emitting device, to reset the anode of the light-emitting device again. The sixth control signal inputted to the sixth control terminal SW−VSS1 of the third voltage selection module 400 is at a high level, and the sixth transistor T60 is cut off. The seventh control signal inputted to the seventh control terminal SW−VSS2 of the third voltage selection module 400 is at a low level, and the seventh transistor T70 is conducted, to transmit the second cathode voltage VSS2 to the second terminal of the light-emitting module 160 (that is, to transmit the second cathode voltage VSS2 to the cathode of the light-emitting device), to ensure that the voltage difference between the first terminal and the second terminal of the light-emitting module 160 does not turn on the light-emitting module 160 in the second reset phase t5.

In the data writing phase t2, the second control signal inputted to the second control terminal SW−Vdata of the first voltage selection module 200 is a low-level signal, and the second transistor T20 is conducted, to transmit the data voltage Vdata to the first voltage input terminal V1. The data writing phase t2 of the display panel includes n data writing sub-phases t21, where n is equal to the number of rows of the pixel circuits 100 in the display panel. Each data writing sub-phase t21 corresponds to the data writing phase t2 of one row of pixel circuits 100. In FIG. 9, S2−Row1 represents a scan line to which control terminals of data writing modules 110 of a first row of pixel circuits 100 in the display panel are connected, S2−Row2 represents a scan line to which control terminals of data writing modules 110 of a second row of pixel circuits 100 in the display panel are connected, and S2−Row3 represents a scan line to which control terminals of data writing modules 110 of a third row of pixel circuits 100 in the display panel are connected. The display panel may include w scan lines S2. Each scan line S2 is correspondingly connected to one row of pixel circuits 100. In the data writing phase t2 of the display panel, in the display panel, signals on the scan line S2−Row1 to which the control terminals of the data writing modules 110 of the first row of pixel circuits 100 are connected, the scan line S2−Row2 to which the control terminals of the data writing modules 110 of the second row of pixel circuits 100 are connected, the scan line S2−Row3 to which the control terminals of the data writing modules 110 of the third row of pixel circuits 100 are connected, . . . , and the scan line S2 to which control terminals of data writing modules 110 of a w^{th} row of pixel circuits 100 are connected are low-level pulses in sequence, and the data writing modules 110 of the first row of pixel circuits 100 to the data writing modules 110 of the w^{th} row of pixel circuits 100 are conducted in sequence, to write the data voltage Vdata to the pixel circuits 100 row by row. The data writing transistor T1 transmits the data voltage Vdata to the first terminal of the coupling module 140, and the first terminal of the coupling module 140 jumps from the initial voltage Vini to the data voltage Vdata. The potential at the first terminal of the coupling module 140 changes from the initial voltage Vini to the data voltage Vdata, with a voltage change at the first terminal of the coupling module 140 being ΔV1=Vdata−Vini. In this case, a voltage at the gate of the driving transistor DT changes correspondingly, with a specific change being

ΔV2=k*(Vdata−Vini),

where

k=C10/(C10+Cother_g),

C10 is a capacitance value of the first capacitor C1, and Cother_g is a capacitance value of another capacitor of the gate. In this case, a potential at the gate of the driving transistor DT is VDD+Vth+k*(Vdata−Vini). The sixth control signal inputted to the sixth control terminal SW−VSS1 of the third voltage selection module 400 is at a high level, and the sixth transistor T60 is cut off. The seventh control signal inputted to the seventh control terminal SW−VSS2 of the third voltage selection module 400 is at a low level, and the seventh transistor T70 is conducted, to transmit the second cathode voltage VSS2 to the second terminal of the light-emitting module 160 (that is, to transmit the second cathode voltage VSS2 to the cathode of the light-emitting device), to ensure that the voltage difference between the first terminal and the second terminal of the light-emitting module 160 does not turn on the light-emitting module 160 in the data writing phase t2.

In the light emission phase t3, the first control signal at the first control terminal SW−Vini of the first voltage selection module 200 and the second control signal at the second control terminal SW−Vdata of the first voltage selection module 200 are both high-level signals, and the first transistor T10 and the second transistor T20 are both cut off. The fourth control signal at the fourth control terminal SW−VDD of the second voltage selection module 300 is a low-level signal, and the fourth transistor T40 is conducted, to transmit the first power supply voltage VDD to the second voltage input terminal. The driving transistor DT is conducted based on the voltage at the gate and the first power supply voltage VDD, to generate a driving current to drive the light-emitting device to emit light. Therefore, in the light emission phase t3,

Vgs−Vth=VDD+Vth+k*(Vdata−Vini)−VDD−Vth,

where Vgs represents a voltage difference between the gate and the first electrode of the driving transistor DT. Therefore, the threshold voltage of the driving transistor DT can be compensated for through the structure of the pixel circuit 100 in the display panel in this embodiment. In this case, in the light emission phase t3, a current of the driving transistor DT is

I=½μ*Cox*W/L*[k(Vdata−Vini)²],

which finally compensates for factors VDD and Vth in a light-emitting current. The sixth control signal inputted from the sixth control terminal SW−VSS1 of the third voltage selection module 400 is at a low level, and the sixth transistor T60 is conducted. The seventh control signal inputted to the seventh control terminal SW−VSS2 of the third voltage selection module 400 is at a high level, and the seventh transistor T70 is cut off, to transmit the first cathode voltage VSS1 to the second terminal of the light-emitting module 160 (that is, to transmit the first cathode voltage VSS1 to the cathode of the light-emitting device), to ensure that the voltage difference between the first terminal and the second terminal of the light-emitting module 160 can turn on the light-emitting module 160 in the light emission phase t3.

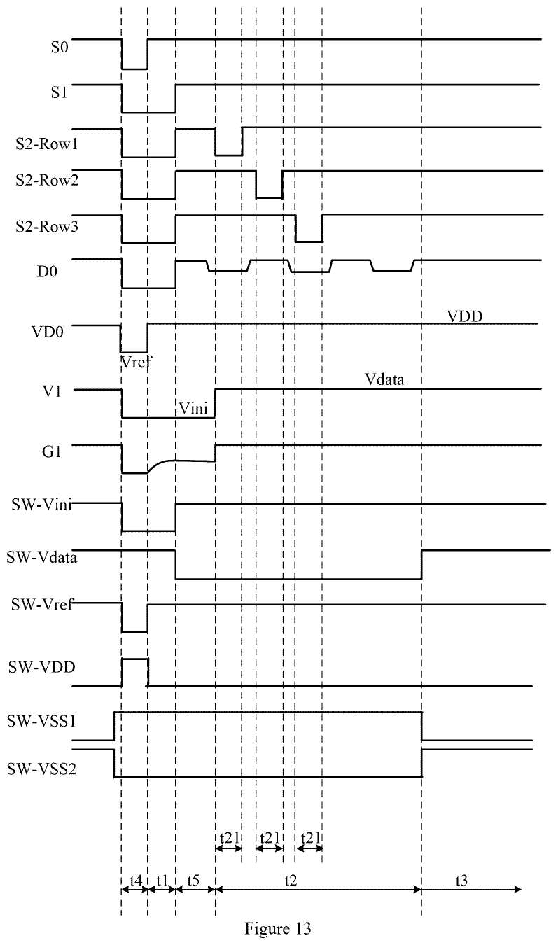

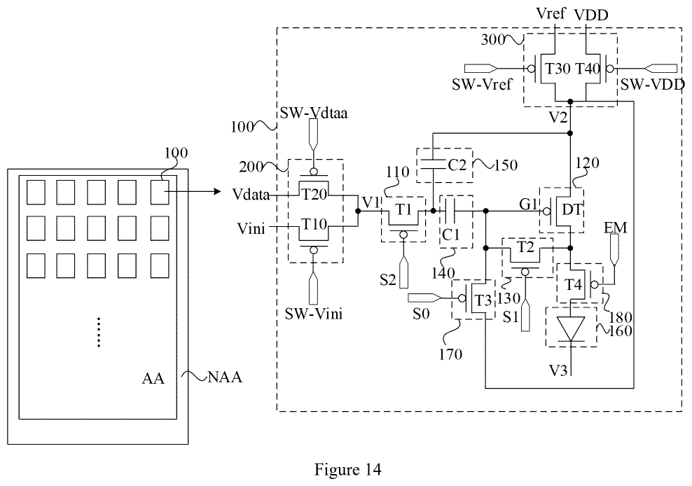

FIG. 14 is a schematic diagram of a structure of another display panel according to an embodiment of the present application. Referring to FIG. 14, in one embodiment, the pixel circuit 100 further includes a light emission control module 180. The light emission control module 180 is provided between the second terminal of the driving module 120 and the first terminal of the light-emitting module 160. The second terminal of the light-emitting module 160 is connected to the third voltage input terminal V3. The light emission control module 180 is configured to be conducted in the light emission phase and cut off in a phase other than the light emission phase based on a signal at a control terminal of the light emission control module 180. In one embodiment, the light emission control module 180 includes a light emission control transistor T4. A gate of the light emission control transistor T4 is used as the control terminal of the light emission control module 180, a first electrode of the light emission control transistor T4 is used as a first terminal of the light emission control module 180 and is electrically connected to the second terminal of the driving module 120, and a second electrode of the light emission control transistor T4 is used as a second terminal of the light emission control module 180 and is electrically connected to the first terminal of the light-emitting module 160.

The display panel may further include light emission control signal lines EM. Each light emission control signal line may be connected to control terminals of light emission control modules 180 of one row of pixel circuits 100, and the light emission control signal line may transmit a light emission control signal to the control terminals of the light emission control modules 180 to which the light emission control signal line is correspondingly connected. The light emission control module 180 is conducted or cut off based on a received light emission control signal. In the light emission phase, the light emission control signal line transmits a conduction control signal to the pixel circuits 100 to which the light emission control signal line is correspondingly connected, and the light emission control module 180 is conducted, and the driving current generated by the driving module 120 can reach the first terminal of the light-emitting module 160 through the light emission control module 180, to drive the light-emitting module 160.

On the basis of the above embodiments, the third voltage input terminal V3 transmits the same voltage to the second terminal of the light-emitting module 160 in the light emission phase and in a phase other than the light emission phase. Specifically, the light emission control module 180 is provided between the second terminal of the driving module 120 and the first terminal of the light-emitting module 160 in the pixel circuit 100, and the light emission control module 180 is cut off in a phase other than the light emission phase. Therefore, in the phase other than the light emission phase, the potential at the second terminal of the driving module 120 cannot reach the first terminal of the light-emitting module 160, which avoids a case in which the light-emitting module 160 is conducted in the phase other than the light emission phase due to an excessively large voltage difference between the first terminal and the second terminal of the light-emitting module 160 caused by an excessively high potential at the second terminal of the driving module 120 in the phase other than the light emission phase. That is, in the display panel of this embodiment, no third voltage selection module 400 needs to be provided, and the light-emitting module 160 is not turned on in a phase other than the light emission phase even if the voltage inputted from the third voltage input terminal V3 remains a fixed voltage. Therefore, the display panel may include a small number of devices, which helps improve the transmittance of the display panel and reduce the bezel width of the display panel.

In one embodiment, the driving module 120 is specifically configured to transmit, to the second terminal of the driving module 120 in the compensation phase, the first power supply voltage VDD inputted from the second voltage input terminal V2, and the compensation module 130 is specifically configured to transmit the voltage at the second terminal of the driving module 120 to the control terminal of the driving module 120 in the compensation phase.

As described above, providing the light emission control module 180 in the pixel circuit 100 can avoid the case in which the light-emitting module 160 is turned on in the phase other than the light emission phase due to an excessively large voltage difference between the first terminal and the second terminal of the light-emitting module 160 caused by an excessively high potential at the second terminal of the driving module 120 in the phase other than the light emission phase. Therefore, in this embodiment, the driving module 120 is configured to transmit, to the second terminal of the driving module 120 in the compensation phase, the first power supply voltage VDD inputted from the second voltage input terminal V2, and the compensation module 130 is specifically configured to transmit the voltage at the second terminal of the driving module 120 to the control terminal of the driving module 120 in the compensation phase, hat is, in the compensation module 130, the voltage inputted from the second voltage input terminal V2 is the first power supply voltage VDD. In the compensation phase, the driving module 120 and the compensation module 130 transmit the first power supply voltage VDD to the control terminal of the driving module 120, to compensate for the threshold voltage of the driving module 120. That is, correspondingly, when the display panel includes the second voltage selection module 300, the second voltage selection module 300 may be the structure shown in FIG. 14, and the second voltage selection module 300 does not need to be connected to the compensation voltage Vcom different from the first power supply voltage VDD. Correspondingly, the second voltage selection module 300 does not need to be provided with the fifth transistor T50, and the structure of the second voltage selection module 300 can be simple, which reduces the number of transistors in the display panel and reduces the routing complexity.

FIG. 14 shows only an example in which the first voltage selection module 200 and the second voltage selection module 300 included in the display panel are both included in the pixel circuit 100. In another embodiment of the present application, either the first voltage selection module 200 or the second voltage selection module 300 may be located in the non-active area NAA, which is not specifically limited in this embodiment.

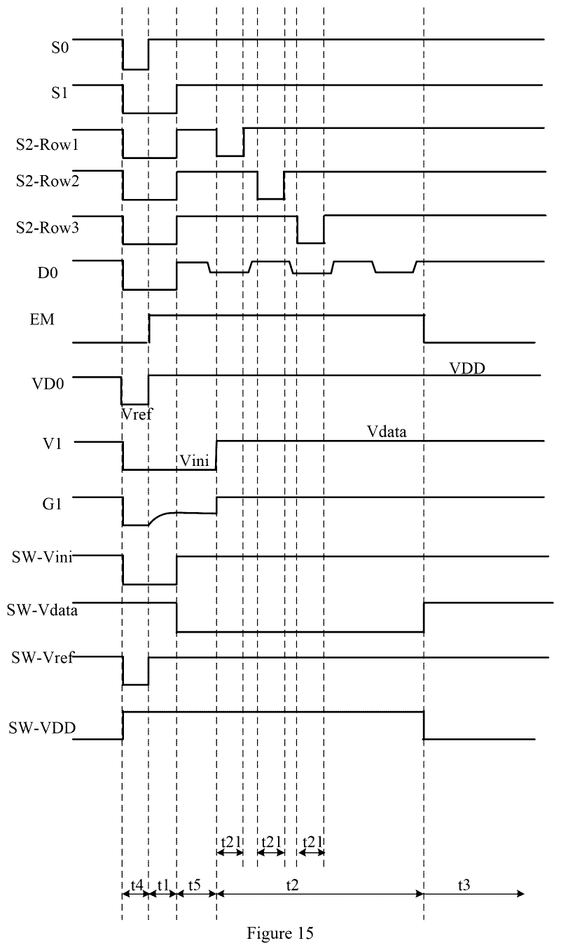

FIG. 15 is a schematic diagram of another type of driving timing for a display panel according to an embodiment of the present application. The driving timing may be used to drive the display panel shown in FIG. 14. An example in which the transistors shown in FIG. 14 are all P-type transistors is used for description. Referring to FIG. 14 and FIG. 15, an operation process of the display panel includes a first reset phase t4, a compensation phase t1, a second reset phase t5, a data writing phase t2, and a light emission phase t3.

Compared with the display panel shown in FIG. 10, in the display panel shown in FIG. 14, except that the third voltage selection module 400 is not included, operation processes of other circuit structures in the display panel in the first reset phase t4, the compensation phase t1, the second reset phase t5, the data writing phase t2, and the light emission phase t3 are the same as that in FIG. 10. Details are not described herein again. Only the operation process of the light emission control module 180 included in the pixel circuit 100 in the display panel shown in FIG. 14 is described below.

In the compensation phase t1, the second reset phase t5, and the data writing phase t2, a light emission control signal to which the gate of the light emission control transistor T4 is connected is a high-level signal, and the light emission control transistor T4 is cut off, and the light-emitting device does not emit light.

In the light emission phase t3, a light emission control signal to which the gate of the light emission control transistor T4 is connected is a low-level signal, and the light emission control transistor T4 is conducted, the driving current generated by the driving transistor DT reaches the anode of the light-emitting device, and the light-emitting device can emit light.

On the basis of the above embodiments, with reference to the types of driving timing for a display panel shown in FIG. 9, FIG. 13 and FIG. 15, in one embodiment, the first reset phases t4 of all of the pixel circuits 100 are performed simultaneously, the compensation phases t1 of all of the pixel circuits 100 are performed simultaneously, the second reset phases t5 of all of the pixel circuits 100 are performed simultaneously, the data writing phases t2 of all rows of pixel circuits 100 are performed row by row, and the light emission phases t3 of all of the pixel circuits 100 are performed simultaneously. That is, the first reset phase of the pixel circuit is denoted as a first reset phase of the display panel, the compensation phase of the pixel circuit is denoted as a compensation phase of the display panel, the second reset phase of the pixel circuit is a reset phase of the display panel, and the light emission phase of the pixel circuit is a light emission phase of the display panel. A data writing phase of the display panel includes the data writing phases of all rows of pixel circuits.

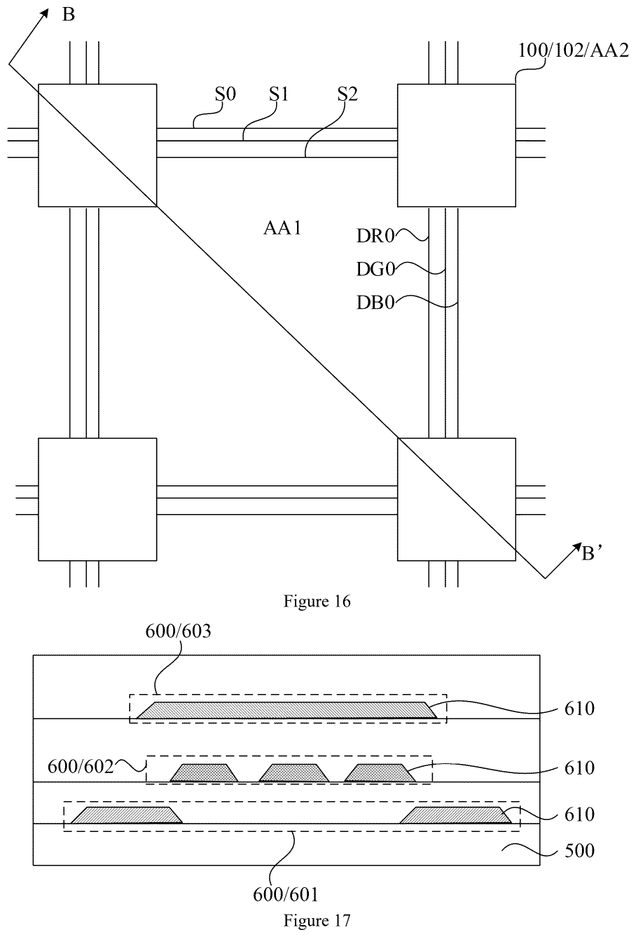

FIG. 16 is an enlarged view of a part in FIG. 1. FIG. 16 may be an enlarged view corresponding to an area 101 marked by a dashed-line box in FIG. 11. Referring to FIG. 16, in one embodiment, the display panel further includes first gate control lines S0, second gate control lines S1, and scan lines S2.

Each row of pixel circuits 100 are correspondingly connected to one first gate control line S0, one second gate control line S1, and one scan line S2. The first gate control line S0 is connected to control terminals of reset modules of the corresponding row of pixel circuits 100, the second gate control line S1 is connected to control terminals of compensation modules of the corresponding row of pixel circuits 100, and the scan line S2 is connected to control terminals of data writing modules of the corresponding row of pixel circuits 100.

Conduction pulse signals on all of the first gate control lines S0 overlap, conduction pulse signals on all of the second gate control lines S1 overlap, first conduction pulse signals on all of the scan lines S2 corresponding to the first reset phase and the compensation phase overlap, and second conduction pulse signals on all of the scan lines S2 corresponding to the data writing phase do not overlap.

Specifically, the conduction pulse signals on all of the first gate control lines S0 overlap, and the first conduction pulse signals on all of the scan lines S2 corresponding to the first reset phase and the compensation phase overlap, which can ensure that the first reset phases of all of the pixel circuits 100 are performed simultaneously. The conduction pulse signals on all of the second gate control lines S1 overlap, and the first conduction pulse signals on all of the scan lines S2 corresponding to the first reset phase and the compensation phase overlap, which can ensure that the compensation phases of all of the pixel circuits 100 are performed simultaneously. The second conduction pulse signals on all of the scan lines S2 corresponding to the data writing phases do not overlap, and the data writing phases of different rows of pixel circuits 100 are not performed simultaneously. Specifically, the second conduction pulse signals on the scan line S2 connected to the first row of pixel circuits 100 to the scan line S2 connected to the last row of pixel circuits 100 may arrive in sequence, to ensure that the data writing phases of all rows of pixel circuits 100 are performed row by row. Conduction pulse signals on all of light emission control lines in the display panel overlap, which can ensure that the light emission phases of all of the pixel circuits 100 in the display panel are performed simultaneously.

Referring to FIG. 16, the data line D0 in the display panel includes a first data line DR0, a second data line DG0, and a third data line DB0. The first data line DR0 is connected to the pixel circuit 100 that drives a red light-emitting device in the display panel, the second data line DG0 is connected to the pixel circuit 100 that drives a green light-emitting device in the display panel, and the third data line DB0 is connected to the pixel circuit 100 that drives a blue light-emitting device in the display panel. The active area AA of the display panel is divided into a light-transmitting area AA1 and a routing area AA2. The pixel circuits 100 are concentrated in the routing area AA2. Every three pixel circuits 100 form one pixel circuit group 102. Each pixel circuit group 102 may include one pixel circuit that drives the red light-emitting device in the display panel, one pixel circuit that drives the green light-emitting device in the display panel, and one pixel circuit that drives the blue light-emitting device in the display panel.

Still referring to FIG. 1 to FIG. 3, FIG. 5 to FIG. 8, FIG. 10 to FIG. 12, and FIG. 14, in one embodiment, a first terminal of the storage module 150 is electrically connected to the first terminal of the driving module 120, and a second terminal of the storage module 150 is electrically connected to the first terminal or the second terminal of the coupling module 140. In the above embodiments of the present application, a case in which the second terminal of the storage module 150 is electrically connected to the first terminal of the coupling module 140 is schematically described. An operation process in a case in which the second terminal of the storage module 150 is electrically connected to the second terminal of the coupling module 140 is similar to the process in the above embodiments. Details are not described herein again. Regardless of whether the second terminal of the storage module 150 is electrically connected to the first terminal or the second terminal of the coupling module 140, the potential at the control terminal of the driving module 120 can be directly or indirectly stored.

As described in the above embodiments, the display panel includes the pixel circuit and a variety of signal lines. The pixel circuit includes the transistor and the capacitor. The transistor, the capacitor, and the signal line usually include a metal material that blocks light. An insulating layer is further provided between different metal layers, and the insulating layer also blocks light to some extent. As a result, diffraction between the different layers is increased, a haze of the display panel is large, and a light transmission effect is poor. In order to reduce the diffraction, reduce the haze, and improve the light transmission effect, an embodiment of the present application provides another display panel. FIG. 17 is a sectional view of a display panel according to an embodiment of the present application. FIG. 17 may correspond to a sectional structure of the routing area in FIG. 16. Referring to FIG. 17, in one embodiment, the display panel further includes a substrate 500 and a driving circuit layer located on a side of the substrate 500, and the pixel circuit 100 is located on the driving circuit layer. The driving circuit layer includes metal layers 600 that are stacked. The metal layer 600 includes a first patterned structure 610, where an edge of an orthographic projection of at least part of the first patterned structure 610 of one metal layer 600 on the substrate 500 is covered by an orthographic projection of at least part of the first patterned structure 610 of another metal layer 600 on the substrate 500.

The first patterned structure 610 includes a constituent structure of a device in the pixel circuit 100. For example, the first patterned structure 610 may be used as a gate, a source, or a drain of a transistor, or may be used as an electrode plate of a capacitor. The first patterned structure 610 further includes a constituent structure of a signal line. The first patterned structure 610 may be directly used as a signal line in the display panel, such as a data line or a scan line. Because the metal material blocks light, an exposed edge of the first patterned structure of the metal layer 600 is prone to diffraction. In this embodiment, the edge of the orthographic projection of at least part of the first patterned structure 610 of one metal layer 600 on the substrate 500 is covered by the orthographic projection of at least part of the first patterned structure 610 of another metal layer 600 on the substrate 500, and the exposed edge of the first patterned structure 610 of the metal layer 600 in the display panel is reduced, thereby reducing interlayer diffraction, and in turn reducing the haze and improving transparency. The exposed edge of the first patterned structure 610 in the embodiments of the present application is an edge that is of an orthographic projection of the first patterned structure 610 on the substrate 500 and that is not covered by an orthographic projection of another light-blocking structure on the substrate 500.

On the basis of the above embodiments, in one embodiment, the driving circuit layer includes n metal layers 600 that are stacked, where n is an integer greater than or equal to 2. An edge of an orthographic projection of at least part of the first patterned structure 610 of any one of (n−1) metal layers 600 on the substrate 500 is covered by orthographic projections of at least part of the first patterned structures 610 of the other metal layers 600 on the substrate 500, and the exposed edge of the first patterned structure 610 of the metal layer 600 in the display panel is further reduced, thereby further reducing the interlayer diffraction, and reducing the haze.

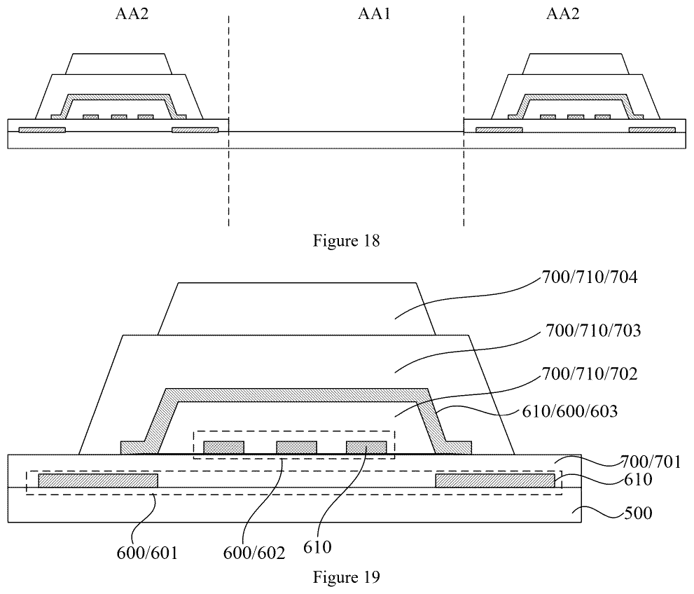

FIG. 18 is a sectional view of another display panel according to an embodiment of the present application. FIG. 18 may be obtained through sectioning along BB′ in FIG. 16. FIG. 19 is a schematic diagram of a specific structure of the routing area in FIG. 18. Referring to FIG. 18 and FIG. 19, in one embodiment, the display panel further includes a substrate 500 and a driving circuit layer located on a side of the substrate 500, and the pixel circuit 100 is located on the driving circuit layer. The driving circuit layer includes metal layers 600 that are stacked and an insulating layer 700 between adjacent metal layers 600.

The metal layer 600 includes a first patterned structure 610, and the insulating layer 700 includes a second patterned structure 710. An edge of an orthographic projection of at least part of the first patterned structure 610 of one metal layer 600 on the substrate 500 is covered by an orthographic projection of at least part of the second patterned structure 710 of one insulating layer 700 on the substrate 500; and/or an edge of an orthographic projection of at least part of the second patterned structure 710 of one insulating layer 700 on the substrate 500 is covered by an orthographic projection of at least part of the first patterned structure 610 of one metal layer 600 on the substrate 500; and/or an edge of an orthographic projection of at least part of the second patterned structure 710 of one insulating layer 700 on the substrate 500 is covered by an orthographic projection of at least part of the second patterned structure 710 of another insulating layer 700 on the substrate 500.

Because the metal material blocks light, the exposed edge of the first patterned structure of the metal layer 600 is prone to diffraction. The insulating layer 700 also blocks light to some extent. Therefore, an exposed edge of the second patterned structure of the insulating layer 700 also has diffraction. Specifically, in this embodiment, the orthographic projection of the second patterned structure 710 of the insulating layer 700 on the substrate 500 covers the edge of the orthographic projection of the first patterned structure 610 of the metal layer 600 on the substrate 500, and/or the orthographic projection of the first patterned structure 610 of the metal layer 600 on the substrate 500 covers the edge of the orthographic projection of the second patterned structure 710 of the insulating layer 700 on the substrate 500, and/or the orthographic projection of the second patterned structure 710 of one insulating layer 700 on the substrate 500 covers the edge of the orthographic projection of the second patterned structure 710 of another the insulating layer 700 on the substrate 500, and the exposed edge of the first patterned structure 610 of the metal layer 600 in the display panel can be reduced, and the exposed edge of the second patterned structure 710 in the display panel can be reduced, thereby reducing the interlayer diffraction, and reducing the haze. The exposed edge of the second patterned structure 710 in the embodiments of the present application is an edge that is of an orthographic projection of the second patterned structure 710 on the substrate 500 and that is not covered by an orthographic projection of another light-blocking structure on the substrate 500. In one embodiment, a distance between the first patterned structures 610 of the same metal layer 600 is greater than or equal to 2 micrometers.

On the basis of the above embodiments, the driving circuit layer includes n metal layers 600 and m insulating layers 700 that are stacked, where n is an integer greater than or equal to 2, and m is an integer greater than or equal to 1.

An edge of an orthographic projection of at least part of the first patterned structure 610 of any one of the metal layers 600 on the substrate 500 is covered by orthographic projections of at least part of the first patterned structures 610 of the other metal layers 600 and/or an orthographic projection of the second patterned structure 710 of an insulating layer 700 on the substrate 500. An orthographic projection of at least part of the second patterned structure 710 of any one of (m−1) insulating layers 700 on the substrate 500 is covered by an orthographic projection of at least part of the first patterned structure 610 of a metal layer 600 and/or orthographic projections of the second patterned structures 710 of the other insulating layers 700 on the substrate 500. In one embodiment, an edge of an orthographic projection of at least part of the second patterned structure 710 of any one of the insulating layers 700 on the substrate 500 is covered by orthographic projections of at least part of the second patterned structures 710 of the other insulating layers 700 or an orthographic projection of the first patterned structure 610 of a metal layer 600 on the substrate 500. An orthographic projection of at least part of the first patterned structure 610 of any one of (n−1) metal layers 600 on the substrate 500 is covered by orthographic projections of at least part of the first patterned structures 610 of the other metal layers 600 and/or an orthographic projection of the second patterned structure 710 of the insulating layer 700 on the substrate 500. That is, in the display panel, the edge of the first patterned structure 610 of only one metal layer 600 is exposed, or the edge of the second patterned structure 710 of only one insulating layer 700 is exposed, thereby minimizing the interlayer diffraction, and in turn reducing the haze and further improving the transparency.

FIG. 17 to FIG. 19 schematically show a structure of three metal layers 600 of the display panel, namely a first metal layer 601, a second metal layer 602, and a third metal layer 603 that are stacked from a side of the substrate 500. In the above embodiments, the second power supply trace may be located on the first metal layer 601, the scan line, the light emission control signal line, and the data line may be located on the second metal layer 602, and the first power supply trace may be located on the third metal layer 603. The scan line and the light emission control signal line have the same extension direction, and an extension direction of the data line is different from the extension direction of the scan line and the light emission control signal line. At an intersection of the data line and the scan line, a routing jump is needed through another metal layer 600, and at an intersection of the data line and the light emission control signal line, a routing jump is also needed through another metal layer 600. Certainly, the signal lines in the display panel may be provided on the layers in another manner, which is not specifically limited in this embodiment. The display panel may include more or fewer metal layers than the three metal layers 600 shown in FIG. 17 to FIG. 19, such as two, four, or more layers, which is not specifically limited in this embodiment. For example, in another embodiment of the present application, the second power supply trace may be flexibly provided on any metal layer 600. For example, the second power supply trace may be provided on the same metal layer as the anode of the light-emitting device in the display panel, and an orthographic projection of the second power supply trace on the substrate 500 is provided to cover the edges of the orthographic projections of at least part of the first patterned structures 610 of the other metal layers 600 in the display panel on the substrate 500.

The display panel shown in FIG. 19 is used as an example. The display panel further includes a first insulating layer 701, a second insulating layer 702, a third insulating layer 703, and a fourth insulating layer 704. The first patterned structure 610 of the third metal layer 603 blocks an edge of a second patterned structure 710 of the second insulating layer 702, an edge of a second patterned structure 710 of the fourth insulating layer 704, and an edge of the first patterned structure 610 of the second metal layer 602. The first patterned structure 610 of the first metal layer 601 blocks an edge of a second patterned structure 710 of the third insulating layer 703 and an edge of the first patterned structure 610 of the third metal layer 603. In this embodiment, the first insulating layer 701 may be an interlayer insulating layer 700 (that is, an insulating layer 700 between the metal layer 600 on which the electrode plate of the capacitor is located and the metal layer 600 on which the source and drain of the transistor are located in the pixel circuit 100), the second insulating layer 702 and the third insulating layer 703 may be planarization layers, and the fourth insulating layer 704 may be a pixel definition layer.

On the basis of the above embodiments, when an edge of an orthographic projection of a first patterned structure 610 (or a second patterned structure 710) on the substrate 500 is covered by an orthographic projection of another first patterned structure 610 (or another second patterned structure 710) on the substrate 500, a distance between the edges of the orthographic projections of the two first patterned structures may be in a range of 2 micrometers to 4 micrometers.

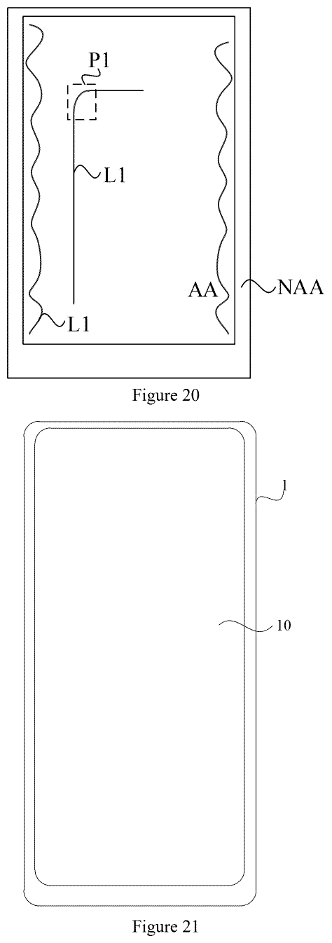

FIG. 20 is a schematic diagram of a structure of another display panel according to an embodiment of the present application. Referring to FIG. 20, on the basis of the above embodiments, a signal line L1 is an arc at a turning position P1 of the signal line L1. In this way, right-angle routing can be avoided, thereby further reducing the diffraction, and in turn reducing the haze and implementing clearer transparent display. The turning position P1 of the signal line L1 is a position at which an extension direction of the signal line L1 changes.

On the basis of the above embodiments, a signal line L1 located at an extreme edge of the active area AA, namely a signal line L1 that is in the active area and that is closest to the non-active area NAA, may be an arc, to further reduce the diffraction, and in turn reduce the haze and implement clearer transparent display. FIG. 20 illustrates a case in which a signal line L1 closest to a left side of the bezel and a signal line L1 closest to a right side of the bezel in the active area are arcs. A signal line L1 closest to an upper side of the bezel and a signal line L1 closest to a lower side of the bezel in the active area are also arcs.

An embodiment of the present application further provides a display apparatus. FIG. 21 is a schematic diagram of a structure of a display apparatus according to an embodiment of the present application. Referring to FIG. 21, a display apparatus 1 provided in this embodiment of the present application includes the display panel 10 provided in any above embodiment of the present application. The display apparatus may be a mobile phone shown in FIG. 21, or may be a computer, a television, a smart wearable display apparatus, or the like. This is not specially limited in this embodiment of the present application.

1. A display panel, comprising:
a plurality of pixel circuits, wherein each pixel circuit comprises a data writing module, a driving module, a compensation module, a coupling module, a storage module, and a light-emitting module;
the data writing module is connected to a first voltage input terminal, and the data writing module is configured to: transmit, to a first terminal of the coupling module in a compensation phase, an initial voltage inputted from the first voltage input terminal; and
transmit, to the first terminal of the coupling module in a data writing phase, a data voltage inputted from the first voltage input terminal;
a second terminal of the coupling module is connected to a control terminal of the driving module; the storage module is configured to store a potential at the control terminal of the driving module; a first terminal of the driving module is connected to a second voltage input terminal;
the compensation module is connected between a second terminal of the driving module and the control terminal of the driving module; and
the driving module is configured to output a driving current to the light-emitting module in a light emission phase through the second terminal of the driving module based on a first power supply voltage inputted from the second voltage input terminal to the first terminal of the driving module and a voltage at the control terminal of the driving module, wherein
the data writing phase is between the compensation phase and the light emission phase.

2. The display panel according to claim 1, further comprising a first voltage selection module, wherein the first voltage selection module comprises a first input terminal, a second input terminal, a first control terminal, a second control terminal, and a first output terminal, the first output terminal is electrically connected to the first voltage input terminal, the first input terminal is connected to the initial voltage, and the second input terminal is connected to the data voltage; and
the first voltage selection module is configured to: transmit the initial voltage to the first voltage input terminal in the compensation phase in response to a first control signal at the first control terminal; and transmit the data voltage to the first voltage input terminal in the data writing phase in response to a second control signal at the second control terminal.

3. The display panel according to claim 2, wherein each pixel circuit comprises one first voltage selection module.

4. The display panel according to claim 2, wherein the first voltage selection module is provided in a non-active area of the display panel, the display panel further comprises a plurality of data lines, the first output terminal of the first voltage selection module is electrically connected to the data line in a one-to-one correspondence, and each data line is connected to first voltage input terminals of one column of pixel circuits.

5. The display panel according to claim 4, wherein the non-active area of the display panel comprises a defined bezel area, the first voltage selection module is located in the defined bezel area, the defined bezel area comprises a lead-out line that leads out a data voltage from a driving chip, and the lead-out line is electrically connected to the data line.

6. The display panel according to claim 1, further comprising a reset module, wherein an input terminal of the reset module is electrically connected to the second voltage input terminal, and an output terminal of the reset module is electrically connected to the control terminal of the driving module; the reset module is configured to transmit, to the control terminal of the driving module in a first reset phase, a reset voltage inputted from the second voltage input terminal; and the compensation module is further configured to be conducted in the first reset phase to transmit, to the second terminal of the driving module, the reset voltage transmitted by the reset module, wherein
the first reset phase is performed before the compensation phase.

7. The display panel according to claim 6, wherein the driving module is further configured to transmit a voltage at the first terminal of the driving module to the second terminal of the driving module in a second reset phase, and the second reset phase is performed between the compensation phase and the data writing phase.

8. The display panel according to claim 6, further comprising a second voltage selection module, wherein the second voltage selection module comprises a third input terminal, a fourth input terminal, a third control terminal, a fourth control terminal, and a second output terminal, the second output terminal is electrically connected to the second voltage input terminal, the third input terminal is connected to the reset voltage, and the fourth input terminal is connected to the first power supply voltage; and
the second voltage selection module is configured to: transmit the reset voltage to the second voltage input terminal in the first reset phase in response to a third control signal at the third control terminal; and transmit the first power supply voltage to the second voltage input terminal in the light emission phase in response to a fourth control signal at the fourth control terminal.

9. The display panel according to claim 8, wherein the second voltage selection module further comprises a fifth input terminal and a fifth control terminal, the fifth input terminal is connected to a compensation voltage, and the compensation voltage is less than the first power supply voltage;
the second voltage selection module is further configured to transmit the compensation voltage to the second voltage input terminal in the compensation phase in response to a control signal at the fifth control terminal; or the second voltage selection module is configured to transmit the first power supply voltage to the second voltage input terminal in the compensation phase in response to the fourth control signal at the fourth control terminal.

10. The display panel according to claim 8, wherein each pixel circuit comprises one second voltage selection module.

11. The display panel according to claim 8, wherein the second voltage selection module is provided in a non-active area of the display panel, the display panel further comprises a plurality of first power supply traces, the second output terminal of the second voltage selection module is electrically connected to the first power supply trace in a one-to-one correspondence, and each first power supply trace is connected to second voltage input terminals of one column of pixel circuits.

12. The display panel according to claim 11, wherein the non-active area of the display panel comprises a defined bezel area, the second voltage selection module is located in the defined bezel area, the defined bezel area comprises a lead-out line that leads out a data voltage from a driving chip, and the lead-out line is electrically connected to a data line of the display panel.

13. The display panel according to claim 1, wherein the second terminal of the driving module is connected to a first terminal of the light-emitting module, a second terminal of the light-emitting module is connected to a third voltage input terminal, the display panel further comprises a third voltage selection module, the third voltage selection module comprises a sixth input terminal, a seventh input terminal, a sixth control terminal, a seventh control terminal, and a third output terminal, the third output terminal is electrically connected to the third voltage input terminal, the sixth input terminal is connected to a first cathode voltage, the seventh input terminal is connected to a second cathode voltage, and the second cathode voltage is greater than the first cathode voltage; the third voltage selection module is configured to: transmit the second cathode voltage to the third voltage input terminal in a phase other than the light emission phase in response to a seventh control signal at the seventh control terminal; and transmit the first cathode voltage to the third voltage input terminal in the light emission phase in response to a sixth control signal at the sixth control terminal;
the driving module is configured to transmit, to the second terminal of the driving module in the compensation phase, the first power supply voltage inputted from the second voltage input terminal, and the compensation module is configured to transmit a voltage at the second terminal of the driving module to the control terminal of the driving module in the compensation phase;
each pixel circuit comprises one third voltage selection module;
or the third voltage selection module is provided in a non-active area of the display panel, and second terminals of light-emitting modules in each column of pixel circuits in the display panel are connected to each other; the display panel further comprises a second power supply trace, one end of the second power supply trace is electrically connected to the third output terminal, and the other end of the second power supply trace is connected to third voltage input terminals of at least one column of pixel circuits; and
the non-active area of the display panel comprises a defined bezel area, the third voltage selection module is located in the defined bezel area, the defined bezel area comprises a lead-out line that leads out a data voltage from a driving chip, and the lead-out line is electrically connected to a data line of the display panel.

14. The display panel according to claim 1, wherein the pixel circuit further comprises a light emission control module, the light emission control module is provided between the second terminal of the driving module and a first terminal of the light-emitting module, and a second terminal of the light-emitting module is connected to a third voltage input terminal; the light emission control module is configured to be conducted in the light emission phase and cut off in a phase other than the light emission phase based on a signal at a control terminal of the light emission control module;
the third voltage input terminal transmits the same voltage to the second terminal of the light-emitting module in the light emission phase and in the phase other than the light emission phase; and
the driving module is configured to transmit, to the second terminal of the driving module in the compensation phase, the first power supply voltage inputted from the second voltage input terminal, and the compensation module is configured to transmit a voltage at the second terminal of the driving module to the control terminal of the driving module in the compensation phase.

15. The display panel according to claim 6, wherein first reset phases of all of the pixel circuits are performed simultaneously, compensation phases of all of the pixel circuits are performed simultaneously, second reset phases of all of the pixel circuits are performed simultaneously, data writing phases of all rows of pixel circuits are performed row by row, and light emission phases of all of the pixel circuits are performed simultaneously.

16. The display panel according to claim 15, wherein the display panel further comprises a plurality of first gate control lines, a plurality of second gate control lines, and a plurality of scan lines;
each row of pixel circuits are correspondingly connected to one of the first gate control lines, one of the second gate control lines, and one of the scan lines, the first gate control line is connected to control terminals of reset modules of the corresponding row of pixel circuits, the second gate control line is connected to control terminals of compensation modules of the corresponding row of pixel circuits, and the scan line is connected to control terminals of data writing modules of the corresponding row of pixel circuits; and
conduction pulse signals on all of the first gate control lines overlap, conduction pulse signals on all of the second gate control lines overlap, first conduction pulse signals on all of the scan lines corresponding to the first reset phase and the compensation phase overlap, and second conduction pulse signals on all of the scan lines corresponding to the data writing phase do not overlap.

17. The display panel according to claim 1, wherein a first terminal of the storage module is electrically connected to the first terminal of the driving module, and a second terminal of the storage module is electrically connected to the first terminal or the second terminal of the coupling module.

18. The display panel according to claim 1, further comprising a substrate and a driving circuit layer located on a side of the substrate, wherein the plurality of pixel circuits are located on the driving circuit layer, and the driving circuit layer comprises a plurality of metal layers that are stacked;
each metal layer comprises a first patterned structure, wherein an edge of an orthographic projection of at least part of the first patterned structure of one metal layer on the substrate is covered by an orthographic projection of at least part of the first patterned structure of another metal layer on the substrate;
the driving circuit layer comprises n metal layers that are stacked, wherein n is an integer greater than or equal to 2; and
an edge of an orthographic projection of at least part of the first patterned structure of any one of (n−1) metal layers on the substrate is covered by orthographic projections of at least part of the first patterned structures of the other metal layers on the substrate.

19. The display panel according to claim 18, wherein the first patterned structure comprises a signal line and a constituent structure of a device in the pixel circuit, wherein at a turning position of the signal line, the signal line is an arc.

20. The display panel according to claim 1, further comprising a substrate and a driving circuit layer located on a side of the substrate, wherein the plurality of pixel circuits are located on the driving circuit layer, and the driving circuit layer comprises a plurality of metal layers that are stacked and an insulating layer between adjacent metal layers;
each metal layer comprises a first patterned structure, and each insulating layer comprises a second patterned structure; an edge of an orthographic projection of at least part of the first patterned structure of one metal layer on the substrate is covered by an orthographic projection of at least part of the second patterned structure of one insulating layer on the substrate; and/or an edge of an orthographic projection of at least part of the second patterned structure of one insulating layer on the substrate is covered by an orthographic projection of at least part of the first patterned structure of one metal layer on the substrate; and/or an edge of an orthographic projection of at least part of the second patterned structure of one insulating layer on the substrate is covered by an orthographic projection of at least part of the second patterned structure of another insulating layer on the substrate;
the driving circuit layer comprises n metal layers and m insulating layers that are stacked, wherein n is an integer greater than or equal to 2, and m is an integer greater than or equal to 1;
an edge of an orthographic projection of at least part of the first patterned structure of any one of the metal layers on the substrate is covered by orthographic projections of at least part of the first patterned structures of the other metal layers or an orthographic projection of at least one of the second patterned structures of the insulating layers on the substrate, and an orthographic projection of at least part of the second patterned structure of any one of (m−1) insulating layers on the substrate is covered by an orthographic projection of at least part of the first patterned structure of the metal layer or an orthographic projection of at least one of the second patterned structures of the other insulating layers on the substrate;
or an edge of an orthographic projection of at least part of the second patterned structure of any one of the insulating layers on the substrate is covered by orthographic projections of at least part of the second patterned structures of the other insulating layers or an orthographic projection of the first patterned structure of the metal layer on the substrate, and an orthographic projection of at least part of the first patterned structure of any one of (n−1) metal layers on the substrate is covered by orthographic projections of at least part of the first patterned structures of the other metal layers or an orthographic projection of at least one of the second patterned structures of the insulating layers on the substrate; and
the first patterned structure comprises a signal line and a constituent structure of a device in the pixel circuit, wherein
at a turning position of the signal line, the signal line is an arc.
